(19) United States
(12) Patent Application Publication
(10) Pub. No.: US 2003/0089965 A1
(43) Pub. Date: May 15, 2003

(54) Bipolar transistor circuit and usage method of bipolar transistor

(76) Inventor: Masaji Haneda, Tokyo (JP)

Correspondence Address: BAKER & MCKENZIE, PATENT DEPARTMENT, 2001 ROSS AVENUE, SUITE 2300, DALLAS, TX, 75201, US

(21) Appl. No.: 10/129,762

(22) PCT Filed: Nov. 29, 2000
(86) PCT No.: PCT/JP00/08387

(30) Foreign Application Priority Data
Sep. 8, 2000 (JP) 2000-272458

(51) Int. Cl. H01L 29/00

(52) U.S. Cl. 257/557

(57) ABSTRACT

Each of an emitter (E), a first collector (CH) and a second collector (CL) is formed from a first conductivity-type area. A breakdown voltage between the first collector (CH) and the base (B) is greater than a breakdown voltage between the second collector (CL) and the base (B). The base (B) is formed from a second conductivity-type area. A positive electrode of a direct-current power source is connected to the first collector (CH) through a load, a negative electrode thereof is connected to the emitter (E), and a control voltage is applied to the base (B). At this time, if the control voltage is equal to or greater than a value determined based on a current flowing between the second collector (CL) and the base (B), a current flows to the load. If the first collector (CH) and the second collector (CL) are connected with each other through a feedback circuit network (RF), and if the positive electrode of the direct-current power source is connected to the first collector (CH) through a resistor, a current which is a signal supplied to the base and amplified (B) flows to this resistor.

### TECHNICAL FIELD

The present invention relates to a bipolar transistor circuit and a usage method of the bipolar transistor, and, more particularly, to a technique for accelerating a switching operation of a switching circuit, a technique for increasing an amplification factor of an amplification circuit, a technique for causing a bipolar transistor to store data or perform oscillation, and a technique for causing a bipolar transistor to stabilize a voltage.

### BACKGROUND ART

To accelerate a switching operation of a switching circuit using a bipolar transistor, or to enhance an amplification factor of an amplification circuit using a bipolar transistor, there is employed a method of forming a Darlington connection circuit using a plurality of bipolar transistors and using the Darlington connection circuit in place of a single bipolar transistor. There is also employed a method of thinning the base of the bipolar transistor.

However, if the bipolar transistor amplifies a signal supplied thereto, the phase of the signal rotates as a result of the Miller capacity of the bipolar transistor, so that an input signal and an output signal are not in exact in-phase or anti-phase.

Thus, in the case where a switching circuit or an amplification circuit is formed using, as a bipolar transistor, a Darlington connection circuit including a plurality of bipolar transistors, there is a switching delay, and the amplified signal is remarkably distorted, as compared to the case where the switching circuit or an amplification circuit is formed using a single bipolar transistor.

In the case where a Darlington connection circuit is used as a bipolar transistor, a saturation voltage when the Darlington connection circuit is saturated (i.e. a voltage between an end of the Darlington connection circuit which serves as a collector and an end thereof which serves as an emitter) gets greater than a voltage between the collector and emitter of a bipolar transistor when the single bipolar transistor is saturated.

Hence, in the case where the switching circuit or amplification circuit is formed with the Darlington connection circuit, there is large power loss in the switching circuit or amplification circuit itself, as compared to the case where the switching circuit or amplification circuit is formed using a single bipolar transistor.

The thinner the base of the bipolar transistor becomes, the lower the withstanding voltage of the base becomes. That is, the thinner the base of the bipolar transistor becomes, the higher the possibility of the breakage of the bipolar transistor becomes upon application of an excessive voltage to the base.

As a memory which is formed using an active element, conventionally, a static memory and dynamic memory are used. In particular, in the case where it is necessary to access the stored contents at a high speed, the static memory is used.

Conventionally, the static memory is formed from a flip-flop circuit including a transistor (a bipolar transistor or a field-effect transistor).

There is a conventionally-known method of forming an oscillator with using means for feeding back an output signal of the flip-flop circuit to an input terminal of the flip-flop circuit. Such an oscillator is widely used for the purpose of generating a clock signal, etc.

In the case where enough power can not be supplied using a method of directly supplying a load with a breakdown voltage generated at both ends of a Zener diode, a constant-voltage circuit shown in FIG. 13 is conventionally used as a method of supplying a stabilized voltage.

As illustrated, this constant-voltage circuit comprises an NPN-type bipolar transistor Tr, a Zener diode Dz, a resistor R and an output terminal Eout.

A positive electrode of an external direct-current power source is connected to a collector of the bipolar transistor Tr through a resistor R, a negative electrode thereof is connected to an emitter, and an anode of a Zener diode Dz is connected to the base. A cathode of the Zener diode Dz is connected to the collector of the bipolar transistor and the output terminal Eout.

In the constant-voltage circuit shown in FIG. 13, if the Zener diode Dz applies such a source voltage for causing a breakdown phenomenon, such as Zener breakdown, avalanche breakdown, etc. from the direct-current power source, the bipolar transistor Tr will be in an ON state by a current flowing to the Zener diode Dz.

This results in a drop in a voltage at the collector of the bipolar transistor Tr and a drop in a voltage at the cathode of the Zener diode Dz connected to the collector. If the voltage between both ends of the Zener diode Dz gets lower than the breakdown voltage, substantially no current flows to the Zener diode Dz.

As a result that an increase or decrease repeatedly occurs in the voltage of the collector transitionally, the voltage at the output terminal Eout is balanced by a value which is approximately equal to a minimum voltage for causing breakdown in the Zener diode Dz.

Thus, by connecting a load between the collector of the bipolar transistor Tr and the negative electrode of the direct-current source-power, a stabilized voltage is supplied to the load.

To form a flip flop circuit, conventionally, at least two transistors are necessary, and further transistor(s) is(are) employed for forming a bias circuit for improving operational characteristics. Hence, the structure of the memory circuit or oscillation circuit having such a flip flop circuit will be complicated.

As a result that the structure of a flip flop circuit will be complicated, it is difficult to make the integration of an integrated circuit including the static memory having the flip-flop circuit, with high density.

In the constant-voltage circuit of FIG. 13, even a current substantially flows from the cathode to anode of the Zener diode Dz, if the size of the current is not large enough to make the bipolar transistor Tr to be ON, the output voltage may not sufficiently be stabilized, depending on the source voltage.

The constant-voltage circuit of FIG. 13 shows output-voltage characteristics shown in FIG. 14, under the assumption that the output voltage is not sufficiently stabilized, with reference to the drawings.

In FIG. 14,

the range identified by [B1] shows an area wherein no breakdown occurs in the Zener diode Dz,

the range identified by [B2] shows an area wherein breakdown occurs in the Zener diode Dz and the bipolar transistor Tr does not get saturated, and

the range identified by [B3] shows an area wherein breakdown occurs in the Zener diode Dz and the bipolar transistor Tr gets saturated.

As illustrated, in the range [B1], the voltage at the output terminal Eout is approximately equal to the source voltage. In the range [B3], the voltage at the output terminal Eout is approximately a constant value. This constant value is approximately equal to a sum of: the breakdown voltage of the Zener diode Dz; and a voltage between the base and emitter of the bipolar transistor Tr in the state where the breakdown voltage is applied between both ends of the Zener diode Dz.

In the range [B2], because the bipolar transistor Tr is not saturated, the size of a current flowing from the base to emitter of the bipolar transistor Tr changes in accordance with the change in the current flowing to the Zener diode Dz.

The voltage of the output terminal Eout is approximately equal to a sum of: a voltage between the Zener diode Dz; and a voltage between the base and emitter of the bipolar transistor Tr. Hence, the voltage between the base and emitter of the bipolar transistor Tr changes in accordance with the forward direction characteristic of a diode including an emitter as its cathode and a base as its anode, upon changing in a forward current flowing between the base and the emitter.

Thus, the voltage at the output terminal Eout in the range [B2] increases at a change rate which is lower than a change rate in the range [B1], in accordance with an increase in the source voltage. That is, in the case where a value of the source voltage is within the range [B2], the voltage at the output terminal Eout is not substantially constant, so that the voltage can not sufficiently be stabilized.

### DISCLOSURE OF INVENTION

This invention has been made in consideration of the above. It is accordingly an object of this invention to provide a bipolar transistor circuit which withstands a high voltage, performs switching at a high speed with very little timing gap, performs amplification with a low level of distortion or a high amplification factor, or operates with little power loss, and also a usage method of realizing such a bipolar transistor circuit.

Another object of this invention is to provide a bipolar transistor circuit which performs oscillation or stores data, is easily formed with a small number of transistors, and is suitable for high-density integration, and also a usage method of realizing such a bipolar transistor circuit.

Still another object of this invention is to provide a bipolar transistor circuit which performs sufficient stabilization of an output voltage and supplies large power, and a method for realizing such a bipolar transistor.

In order to achieve the above objects, a bipolar transistor according to the first aspect of this invention may includes a structure (Q) for performing switching while withstanding a high voltage or performing amplification with a high amplification factor, reducing power loss, performing oscillation with a simple structure or storing data, or stabilizing an output voltage and supplying large power.

A bipolar transistor circuit according to the second aspect of the present invention may include a current path (CH, E), determines, when a trigger signal and a bias signal are supplied to the bipolar transistor circuit, whether intensity of the trigger signal has reached a threshold value determined based on intensity of the bias signal, and controls opening and closing of the current path in accordance with a result of determination, the bipolar transistor including

a bipolar transistor (Q) which comprises: a first conductivity-type emitter (E); a second conductivity-type base (B) connected to the emitter; a first conductivity-type first collector (CH) connected to the base; and a first conductivity-type second collector (CL) connected to the base, and wherein a breakdown voltage of a junction surface of the base and the second collector is lower than a breakdown voltage of a junction surface of the base and the first collector, and

wherein

the emitter of the bipolar transistor forms one end of the current path,

the first collector of the bipolar transistor forms other end of the current path,

the bipolar transistor

causes a current to flow between the emitter and the base, when the trigger signal is supplied to the base,

causes the breakdown voltage of the junction surface of the second collector and the base to be changed in accordance with size of the current flowing between the emitter and the base,

causes, when a voltage of the junction surface of the second collector and the base reaches the breakdown voltage as a result that the bias signal is supplied to the second collector and the trigger signal is supplied to the base, breakdown to occur on the junction surface, thereby conductivity is made on the junction surface and a breakdown current flows on the junction surface, and

causes conductivity to be made between the first collector and the emitter, when the breakdown voltage flows.

Such a bipolar transistor circuit causes a breakdown current to be flowing between the second collector and base of the bipolar transistor. When this breakdown current flows, the first collector and the emitter are ON. Because the breakdown current generated by a breakdown phenomenon is remarkably multiplied within a short period of time, such a bipolar transistor circuit performs switching at a high speed with very little switching gap.

It is not necessary that the base of the bipolar transistor in such a bipolar transistor circuit be thinner than the base of a general bipolar transistor, and hence maintaining high voltage withstanding.

Further, such a bipolar transistor circuit does not include any Darlington connection circuit. Hence, a voltage between the first collector and the emitter gets almost as low as the voltage between the collector and the emitter during the saturation time of a general bipolar transistor, and hence resulting in very little power loss.

The smaller the area of the junction surface of the base and first collector of the bipolar transistor becomes, the smaller the junction capacity of the junction surface of the base and the first collector becomes as well. Thus, the smaller the area of the junction surface of the base and the first collector becomes, the better the frequency characteristics of the bipolar transistor becomes, and hence accelerating the switching speed.

In the case where the area of the junction surface of the base and first collector of the bipolar transistor is smaller than the area of the junction surface of the base and the emitter, the bipolar transistor circuit performs switching at a higher speed than the case where the area of the junction surface of the base and the first collector is equal to or larger than the area of the junction surface of the base and the emitter.

In the case where the area of the junction surface of the base and emitter of the bipolar transistor is smaller than the area of the junction surface of the base and the first collector, the input impedance of the bipolar transistor circuit gets greater than the case where the area of the junction surface of the base and emitter is equal to or larger than the area of the junction surface of the base and the first collector.

A bipolar transistor circuit according to the third aspect of the present invention may include a current path (CH, E), and causes an output current representing a signal which is an amplified input signal supplied to the bipolar transistor circuit to be flowing to the current path, and the bipolar transistor comprising:

a bipolar transistor which comprises a first conductivity-type emitter (E), a second conductivity-type base (B) connected to the emitter, a first conductivity-type collector (CH) connected to the base, and a first conductivity-type second collector (CL) connected to the base, and wherein a breakdown voltage of the junction surface of the base and the first collector is higher than a breakdown voltage of the junction surface of the base and the second collector; and

a feedback circuit network (RF) which is connected between the first collector and the second collector of the bipolar transistor, and

wherein

the emitter of the bipolar transistor forms one end of the current path,

the first collector of the bipolar transistor forms other end of the current path,

a breakdown current flows to the junction surface of the second collector and base of the bipolar transistor,

the output current whose size is determined based on a size of the breakdown current flows to the junction surface of the first collector and base of the bipolar transistor, when the breakdown current flows to the junction surface of the second collector and base of the bipolar transistor, and

the size of the breakdown current is determined based on intensity of the input signal supplied to the base of the bipolar transistor and intensity of a feedback signal to be supplied to the second collector of the bipolar transistor through the feedback circuit network.

Such a bipolar transistor circuit causes a breakdown current to be flowing between the second collector and base of the bipolar transistor, and causes an output current whose size corresponds to the size of this breakdown current to be flowing between the first collector and the emitter. A breakdown current which is generated by a breakdown phenomenon is remarkably multiplied within a short period of time. Hence, such a bipolar transistor circuit changes the output current in accordance with the high-speed change of the input signal. Thus, the frequency characteristics of such a bipolar transistor circuit are better than that including a general bipolar transistor or a Darlington connection circuit.

This breakdown current is generally larger than a current, which flows between the second collector and the emitter as a result that an input signal is supplied to the base and that a current amplification function of the bipolar transistor occurs. Thus, the amplification factor of such a bipolar transistor circuit gets greater than that including a general bipolar transistor. Negative feedback is performed by the feedback circuit network, thereby eliminating the distortion.

It is not necessary that the base of the bipolar transistor of such a bipolar transistor be thinner than the base of a general bipolar transistor, and hence maintaining high voltage withstanding.

Further, since such a bipolar transistor circuit does not include a Darlington connection circuit, a voltage between the first collector and the emitter gets almost as low as a voltage between the collector and the emitter of a general bipolar transistor while being saturated, and the power loss is very little.

The smaller the area of the junction surface of the base and first collector of the bipolar transistor becomes, the smaller the junction capacity of the junction surface of the base and the first collector becomes. Thus, the smaller the area of the junction surface of the base and the first collector, the better the frequency characteristics of the bipolar transistor, and hence improving the switching speed.

Hence, in the case where an area of the junction surface of the base and first collector of the bipolar transistor is smaller than an area of the junction surface of the base and the emitter, the frequency characteristics of the bipolar transistor circuit are better than that of the bipolar transistor circuit in the case where the area of the junction surface of the base and the first collector is equal to or larger than the area of the junction surface of the base and the emitter.

In the case where an area of the junction surface of the base and emitter of the bipolar transistor is smaller than an area of the junction surface of the base and the first collector, the input impedance of the bipolar transistor circuit gets greater than that of the bipolar transistor circuit in the case where the area of the junction surface of the base and the emitter is equal to or larger than the area of the junction surface of the base and the first collector.

The ratio of the size of the breakdown current to the size of the current, which flows between the emitter and base upon supplying of an input signal, is larger than the current amplification factor of a general bipolar transistor. Even if the area of the junction surface of the base and the emitter is smaller than the area of the junction surface of the base and the first collector, a sufficient amplification factor can be ensured.

A bipolar transistor circuit according to the fourth aspect of this invention may include a pair of ends, and supplies substantially a constant stabilized voltage from the pair of ends when a voltage is applied through a load (R1) which is cascaded to the bipolar transistor circuit, and the bipolar transistor including

a bipolar transistor (Q) which comprises a first conductivity-type emitter (E), a second conductivity-type base (B) connected to the emitter, a first conductivity-type first collector (CH) connected to the base, and a first conductivity-type second collector (CL) connected to the base, and wherein a breakdown voltage of a junction surface of the base and the first collector is higher than a breakdown voltage of a junction surface of the base and the second collector, and

wherein:

the emitter forms one of the pair of ends;

the first and second collectors are connected with each other so as to form other one of the pair of ends; and

the stabilized voltage is supplied from the pair of ends, when a voltage for causing a reverse voltage equal to or greater than the breakdown voltage of the junction surface of the base and the second collector to be applied to the junction surface of the base and second collector of the bipolar transistor is applied to the pair of ends.

According to such a bipolar transistor circuit, if a current substantially flows from the second collector to base of the bipolar transistor, the first collector to the emitter will immediately be in an ON state. Hence, the size of the current flowing from the collector to the base does not remarkably change. Thus, in this bipolar transistor circuit, it is prevented that the voltage between the base and emitter of the bipolar transistor substantially changes.

Thus, according to such a bipolar transistor circuit, a constant-voltage circuit, which sufficiently stabilizes the output voltage and supplies large power, can easily be formed.

A bipolar transistor circuit according to the fifth embodiment of this invention may comprise:

a bipolar transistor which includes a first conductivity-type emitter (E), a second conductivity-type base (B) connected to the emitter, a first conductivity-type first collector (CH) connected to the base, and a first conductivity-type second collector (CL) connected to the base, and wherein a breakdown voltage of a junction surface of the base and the first collector is greater than a breakdown voltage of a junction surface of the base and the second collector;

a circuit network (R2) which applies a reverse voltage which is lower than the breakdown voltage of the junction surface to the junction surface of the base and second collector of the bipolar transistor, when a bias voltage is externally applied; and

a load (R3) which is cascaded to a section whose ends are the first collector and emitter of the bipolar transistor, and

wherein a source voltage is applied to both ends of a series circuit including the section and the load, the bias voltage is applied to the circuit network, and a signal representing a size of a current flowing to the series circuit is supplied as an output signal representing a value represented by a latest input signal applied to the base, when the input signal is applied to the base of the bipolar transistor.

According to such a bipolar transistor circuit, the passage of a current flowing between the first collector and the emitter and between the second collector and the emitter is accelerated and restricted, in accordance with a current, which is supplied to the base upon application of an input signal to the base of the bipolar transistor. Even if the current stops to be supplied to the base, the same ON state or OFF state is maintained as the state just before the current stops to be supplied thereto, between the first collector and the emitter and between the second collector and the emitter. Then, the output signal reflects the maintained ON or OFF state. That is, the bipolar transistor stores information represented by the latest input signal applied to the base.

Such a bipolar transistor is formed from a single transistor, and hence suitable for high-density integration.

A bipolar transistor circuit according to the sixth aspect of this invention may comprise:

a bipolar transistor comprising a first conductivity-type emitter (E), a second conductivity-type base (B) connected to the emitter, a first conductivity-type first collector (CH) connected to the base, and a first conductivity-type second collector (CL) connected to the base, and wherein a breakdown voltage of a junction surface of the base and the first collector is greater than a breakdown voltage of a junction surface of the base and the second collector; and

a feedback circuit network (CT, RT) which applies a voltage representing a substantially delayed signal representing a voltage of the first collector of the bipolar transistor, to the junction surface of the base and second collector of the bipolar transistor, and

wherein the bipolar transistor circuit outputs an oscillation signal representing a size of a current flowing to the first collector of the bipolar transistor.

According to such a bipolar transistor, a bias current flows to the base of the bipolar transistor, thereby the section among the first and second collectors and the emitter is set ON. After this, if the supplying of the bias current substantially stops, the section among the first and second collectors and the emitter is set OFF. The voltage between the second collector and the emitter increases, and the voltage between the second collector and the emitter becomes a breakdown voltage. In this case, the breakdown occurs on the junction surface between the second collector and the emitter, and the junction surface will be ON. As a result of this, the potential of the base rises, and the section between the first collector and the emitter will be ON. Thus, the voltage of the first collector periodically goes up and down, thereby obtaining an oscillation signal.

Such a bipolar transistor circuit can easily be formed using a single transistor. Hence, a circuit including such a bipolar transistor is suitable for high-density integration.

A trigger signal for setting the bipolar transistor ON and OFF may be supplied to the base of the bipolar transistor. When the trigger signal is supplied to the base, if the bipolar transistor circuit outputs or stops outputting the oscillation signal in accordance with the trigger signal, whether the oscillation signal is output or stops to be output is controlled from an external section.

In the bipolar transistor circuit according to the fourth, fifth and sixth aspects of this invention,

the bipolar transistor may include a first conductivity-type control layer (CONT) connected to the based; and

the breakdown voltage of the junction surface of the base and the control layer may be greater than the breakdown voltage of the junction surface of the base and the second collector.

In this structure, the size of the current flowing from the second collector to base of the bipolar transistor is controlled also by a voltage applied to the control layer. Thus, the stabilized voltage supplied by the bipolar transistor circuit, the threshold value of the input signal for shifting the logical state represented by the output signal, the frequency of the oscillation signal are controlled in accordance with the voltage applied to the control layer.

A usage method of a bipolar transistor, according to the seventh aspect of this invention may include a step of realizing

a bipolar transistor circuit which performs switching while withstanding a high voltage or performs amplification with a high amplification factor,

a bipolar transistor circuit which operates with little power loss,

a bipolar transistor circuit which performs oscillation with a simple structure or stores data, or

a bipolar transistor circuit which stabilizes an output voltage and performs supplying of large power.

A usage method of a bipolar transistor, according to the eighth aspect of this invention may comprise a first conductivity-type emitter, a second conductivity-type base connected to the emitter, a first conductivity-type first collector connected to the base, and a first conductivity-type second collector connected to the base, and the method is for controlling conductivity and non-conductivity between the emitter and first collector of the bipolar transistor, and the method comprising:

changing a breakdown voltage of a junction surface of the first collector and the base, in accordance with a size of a current flowing between the emitter and the second collector and a size of a current flowing between the emitter and the base; and

supplying the base with a trigger signal and setting a voltage of the junction surface of the first collector and the base to reach the breakdown voltage, and causing breakdown on the junction surface so as to make conductivity on the junction surface and conductivity between the emitter and the first collector.

According to such a method for a bipolar transistor, a current flows between the first collector and base of the bipolar transistor, as a result of a breakdown phenomenon. The breakdown current generated as a result of the breakdown phenomenon is suddenly multiplied within a short period of time. Hence, according to such a usage method of a bipolar transistor, the switching is achieved at a high speed with very little timing gap of the switching.

It is not necessary that the base of the bipolar transistor controlled in accordance with such a usage method be thinner than the base of a general bipolar transistor, and hence ensuring high withstanding voltage.

Further, such a usage method of a bipolar transistor is not for forming a Darlington connection circuit, the voltage between the first collector and the emitter gets almost as low as the voltage between the collector and emitter of a general bipolar transistor while being saturated, and the power loss is very little.

In the case where the area of the junction surface of the base and emitter of the bipolar transistor is smaller than the area of the junction surface of the base and the first collector, the input impedance of the base of the bipolar transistor is greater than that of the bipolar transistor wherein the area of the junction surface of the base and the emitter is equal to or larger than the area of the junction surface of the base and the first collector.

The size of the breakdown current flowing to the junction surface of the first collector and the base is controlled by controlling, for example, the size of the current flowing between an external section and the base and the size of a current flowing between an external section and the second collector.

If the breakdown voltage of the junction surface of the first collector and the base and the breakdown voltage of the junction surface of the second collector and the base are different from each other, breakdown can easily occur selectively on the junction surface of the first collector and the base.

A usage method of a bipolar transistor, according to the ninth aspect of this invention may comprise a first conductivity-type emitter, a second conductivity-type base connected to the emitter, a first conductivity-type first collector connected to the base, and a first conductivity-type second collector connected to the base, and the method is for changing a breakdown voltage of a junction surface of the first collector and base of the bipolar transistor, and the method comprising

changing the breakdown voltage of the junction surface of the first collector and the base, by changing a size of a current flowing between the emitter and the second collector and a size of a current flowing between the emitter and the base.

According to such a usage method of a bipolar transistor, the breakdown current, generated between the first collector and base of the bipolar transistor as a result of a breakdown phenomenon, is suddenly multiplied within a short period of time. Hence, an amplification function, wherein an output current keeps up with a high-speed change of the input signal, is realized. The frequency characteristics of such an amplification function are better than the frequency characteristics of an amplification circuit including a general bipolar transistor or a Darlington connection circuit.

This breakdown current is generally greater than a current, flowing between the first collector and the emitter upon supplying of an input signal to the base. Thus, the amplification factor in such an amplification function is greater than an amplification factor of an amplification circuit including a general bipolar transistor.

It is not necessary that the base of the bipolar transistor used in such a usage method be thinner than the base of a general bipolar transistor, and hence ensuring high withstanding voltage.

Since such a usage method of a bipolar transistor is not for forming a Darlington connection circuit, the voltage between the first collector and the emitter gets almost as low as the voltage between the collector and the emitter of a general bipolar transistor while being saturated, and the power loss is very little. The size of the breakdown current flowing to the junction surface of the first collector and the base can be controlled by controlling, for example, the size of the current flowing between an external section and the base and the size of the current flowing between an external section and the second collector.

If the area of the junction surface of the base and emitter of the bipolar transistor is set smaller than the area of the junction surface of the base and the first collector, the input impedance of the base of the bipolar transistor gets larger than that of a bipolar transistor wherein the area of the junction surface of the base and the emitter is equal to or greater than the area of the junction surface of the base and the first collector.

If the breakdown voltage of the junction surface of the first collector and the base and the breakdown voltage of the junction surface of the second collector and the base are different from each other, it is easy to selectively change a breakdown state of the junction surface of the first collector and the base.

A usage method of the bipolar transistor according to the tenth aspect of this invention may be for a bipolar transistor which comprises a first conductivity-type emitter, a second conductivity-type base connected to the emitter, a first conductivity-type first collector connected to the base, and a first conductivity-type second collector connected to the base, and wherein a breakdown voltage of a junction surface of the base and the first collector is greater than a breakdown voltage of a junction surface of the base and the second collector, and the method may be for causing the bipolar transistor to generate substantially a constant stabilized voltage, and for

connecting the first and second collectors with each other, and

applying such a voltage that a reverse voltage which is equal to or greater than a breakdown voltage on the junction surface of the base and the second collector of the bipolar transistor, between a first node including the emitter and a second node including a connection point of the first collector and the second collector, through a load cascaded to a current path including the first and second nodes, thereby causing the stabilized voltage to be generated between the first and second nodes.

According to such a usage method of a bipolar transistor, if a current substantially flows from the second collector to base of the bipolar transistor, a section between the first collector and the emitter will immediately be in an ON state. Thus, the size of the current flowing from the second collector to the base does not largely change. Hence, according to such a usage method of a bipolar transistor, it is prevented that the voltage between the base and emitter of a bipolar transistor substantially changes.

Thus, according to such a usage method of a bipolar transistor, it is easy to form a constant-voltage circuit which sufficiently stabilizes the output voltage and supplies large power.

A usage method of a bipolar transistor according to the eleventh aspect of this invention may be for a bipolar transistor which comprises a first conductivity-type emitter, a second conductivity-type base connected to the emitter, a first conductivity-type first collector connected to the base, and a first conductivity-type second collector connected to the base, and wherein a breakdown voltage of a junction surface of the base and the first collector is greater than a breakdown voltage of a junction surface of the base and the second collector, and the method may comprise applying an input signal to the base of the bipolar transistor,

applying a reverse voltage which is lower than the breakdown voltage of the junction surface of the base and the second collector, to this junction surface of the bipolar transistor,

cascade-connecting a load to a section whose ends are the first collector and emitter of the bipolar transistor, and

applying a voltage between both ends of a series circuit including the section and the load, thereby causing a current, representing a value represented by the latest input signal applied to the base, to flow to the series circuit.

According to such a usage method of a bipolar transistor, in accordance with a current flowing upon application of an input signal to the base of the bipolar transistor, the passage of a current is accelerated and restricted between the first collector and the emitter and the second collector and the emitter. Even if the current stops to be supplied to the base, the same ON state or OFF state is maintained as the state just before the current stops to be supplied thereto, between the first collector and the emitter and between the second collector and the emitter. Then, the output signal reflects the maintained ON or OFF state. That is, the bipolar transistor stores information represented by the latest input signal applied to the base.

Such a usage method of a bipolar transistor is easily realized using a single transistor, and thus suitable for high density integration of the bipolar transistor.

A usage method of a bipolar transistor according to the twelfth aspect of this invention may be for a bipolar transistor which comprises a first conductivity-type emitter, a second conductivity-type base connected to the base, a first conductivity-type first collector connected to the base, and a first conductivity-type second collector connected to the base, and wherein a breakdown voltage of a junction surface of the base and the first collector is greater than a breakdown voltage of a junction surface of the base and the second collector, and the method may comprise

applying a voltage representing a substantially delayed signal representing the voltage of the first collector of the bipolar transistor, onto the junction surface of the base and the second collector, thereby causing an oscillating current to flow to the first collector of the bipolar transistor.

According to such a usage method of a bipolar transistor, a bias current flows to the base of the bipolar transistor, thereby a section among the first and second collectors and the emitter is set ON. After this, if the supplying of the bias current substantially stops, the section among the first and second collectors and the emitter will be OFF. If the voltage between the second collector and the emitter increases, and the voltage between the second collector and the emitter is a breakdown voltage, breakdown occurs on the junction surface of the second collector and the emitter, and the junction surface will be ON. As a result of this, the potential of the base increases, and the section between the first collector and the emitter will be ON. Thus, the voltage of the first collector periodically goes up and down, and hence obtaining an oscillation signal.

Such a usage method of a bipolar transistor can easily be realized using a single transistor. Hence, such a usage method of a bipolar transistor is suitable for high-density integration of the bipolar transistor.

In the usage method of a bipolar transistor, if a trigger signal for setting the bipolar transistor ON and OFF is supplied to the base of the bipolar transistor, the current flowing to the first collector is intermittently controlled.

A usage method of a bipolar transistor, according to the thirteenth aspect of this invention may comprise:

forming a second conductivity-type base connected to a first conductivity-type emitter;

forming a first conductivity-type first collector connected to the base; and

forming a first conductivity-type second collector which is connected to the base, and wherein a breakdown voltage of a junction surface to the base is lower than a breakdown voltage of the base and the first collector.

A usage method of a bipolar transistor according to the fourteenth aspect of this invention may comprise:

forming a second conductivity-type base connected to a first conductivity-type emitter;

forming a first conductivity-type first collector connected to the base; and

forming a first conductivity-type second collector which has impurity density higher than impurity density of the first collector and is connected to the base. As a result that the second collector has higher impurity density than that of the first collector, the breakdown voltage of the junction surface of the base and the second collector gets lower than the breakdown voltage of the junction surface of the base and the first collector.

In a bipolar transistor which is manufactured in accordance with the above usage methods of a bipolar transistor, the breakdown voltage of the junction surface of the second collector and the base is determined based on the intensity of a signal supplied to the base and the intensity of a signal supplied to the second collector. Such a bipolar transistor causes a breakdown current which is radically multiplied within a short period of time to be flowing between the second collector and the base, as a result of a breakdown phenomenon. Hence, the switching circuit including such a bipolar transistor performs switching at a high speed with very little switching gap.

This breakdown current is generally greater than a current, which flows between the second collector and the emitter upon occurrence of a current amplification function of the bipolar transistor as a result of supplying of an input signal to the base. Thus, the amplification factor of an amplification circuit including such a bipolar transistor gets high. Further, the negative feedback is performed, thereby eliminating the distortion.

It is not necessary that the base of such a bipolar transistor be thinner than the base of a general bipolar transistor, and thus maintaining high withstanding voltage.

Further, such a bipolar transistor is not for forming a Darlington connection circuit. Thus, the voltage between the first collector and the emitter gets almost as low as the voltage between the collector and emitter of a general bipolar transistor while being saturated, and hence resulting in very little power loss.

Such a bipolar transistor causes changes an output current, in accordance with a high-speed change of the input signal supplied to the base. Thus, if an amplification circuit is formed using such a bipolar transistor, the frequency characteristics of the amplification circuit are improved compared to the case where an amplification circuit is formed using a general bipolar transistor or a Darlington connection circuit.

The smaller the area of the junction surface of the base and first collector of the bipolar transistor, the smaller the junction capacity of the junction surface of the base and the first collector. Thus, the smaller the area of the junction surface of the base and the first collector, the better the frequency characteristics of the bipolar transistor, and hence improving the switching speed.

Thus, in the case where the area of the junction surface of the base and first collector of the bipolar transistor is smaller than the area of the junction surface of the base and the emitter, the frequency characteristics of the bipolar transistor are better than that of a bipolar transistor wherein the area of the junction surface of the base and the first collector is equal to or larger than the area of the junction surface of the base and the emitter.

In the case where the area of the junction surface of the base and first collector of the bipolar transistor is smaller than the area of the junction surface of the base and the emitter, the switching speed of the bipolar transistor is faster than that of a bipolar transistor wherein the area of the junction surface of the base and the first collector is equal to or larger than the area of the junction surface of the base and the emitter.

If the area of the junction surface of the base and emitter of the bipolar transistor is smaller than the area of the junction surface of the base and the first collector, the input impedance of the amplification circuit gets larger than that of a bipolar transistor wherein the area of the junction surface of the base and emitter is equal to or larger than the area of the junction surface of the base and the first collector.

The ratio of the size of a breakdown current, flowing between the second collector and the base, to the size of a current flowing between the emitter and the base upon supplying of a signal from an external section to the base, is greater than a current amplification factor of a general bipolar transistor. Hence, in an amplification circuit including such a bipolar transistor, even if the area of the junction surface of the base and the emitter is smaller than the area of the junction surface of the base and the first collector, a sufficient amplification factor can be ensured.

The usage method of a bipolar transistor according to the thirteenth aspect of this invention may comprise

forming a first conductivity-type control layer, which is connected to the base and wherein a breakdown voltage of a junction surface to the base is greater than a breakdown voltage of a junction surface of the base and the second collector.

The usage method of a bipolar transistor according to the fourteenth aspect of this invention may comprise

forming a first conductivity-type control layer which has impurity density lower than that of the second collector and which is connected to the base.

Because the bipolar transistor includes such a control layer, the size of a current flowing from the second collector to base of the bipolar transistor is controlled based on a voltage applied to the control layer.

### BRIEF DESCRIPTION OF DRAWINGS

FIG. 1 is a circuitry diagram showing the structure of a switching circuit according to the first embodiment of this invention.

FIG. 2 is an exemplary cross-sectional view showing the structure of a transistor in the switching circuit of FIG. 1.

FIG. 3 is a circuitry diagram showing the structure of an amplification circuit according to the second embodiment of this invention.

FIG. 4 is a circuitry diagram showing the structure of a constant-voltage circuit according to the third embodiment of this invention.

FIG. 5 is a graph showing an output voltage characteristic of the constant-voltage circuit of FIG. 4.

FIG. 6 is a circuitry diagram showing the structure of a memory circuit according to the fourth embodiment of this invention.

FIG. 7 is a circuitry diagram showing the structure of an oscillation circuit according to the fifth embodiment of this invention.

FIG. 8 is an exemplary cross-sectional view showing the structure of a modification of the transistor of FIG. 2.

FIG. 9 is an exemplary cross-sectional view showing the structure of a modification of the transistor of FIG. 2.

FIG. 10 is a circuitry diagram showing the structure of a modification of the constant-voltage circuit of FIG. 4.

FIG. 11 is a circuitry diagram showing the structure of a modification of the memory circuit of FIG. 6.

FIG. 12 is a circuitry diagram showing the structure of a modification of the oscillation circuit of FIG. 7.

FIG. 13 is a circuitry diagram showing the structure of a modification of a conventional constant-voltage circuit.

FIG. 14 is a graph showing an output voltage characteristic of the constant-voltage circuit of FIG. 13.

### BEST MODE FOR CARRYING OUT THE INVENTION

Embodiments of this invention will now be explained with reference to the accompanying drawings.

(First Embodiment: Switching Circuit)

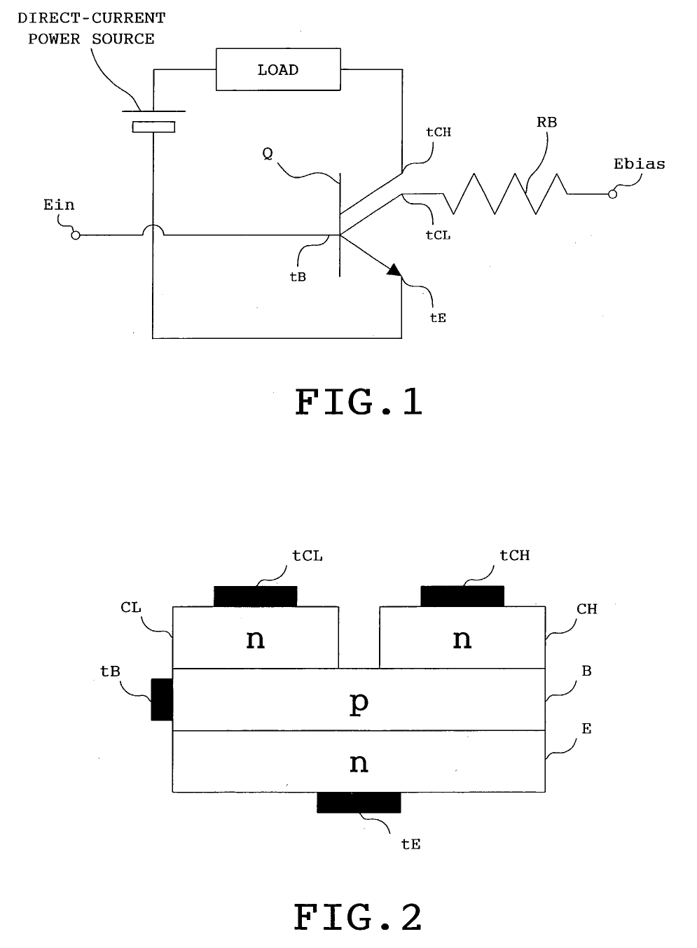

FIG. 1 is a circuitry diagram showing the structure of a switching circuit according to the first embodiment of this invention. As illustrated, this switching circuit includes a transistor Q, a resistor RB, a signal-input terminal Ein and a bias terminal Ebias.

The transistor Q has the structure shown in FIG. 2, for example.

As illustrated, the transistor Q includes a high-voltage collector CH, a low-voltage collector CL, a base B and an emitter E.

Both of the high-voltage collector CH and the low-voltage collector CL are formed from an n-type semiconductor area (hereinafter referred to as an n-type area), and are not in contact with each other while being directly connected to the base B.

A high-voltage collector terminal tCH, for external connection, is connected to the high-voltage collector CH, while a low-voltage collector terminal tCL, for external connection, is connected to the low-voltage collector CL.

A voltage (a breakdown voltage), at which a breakdown occurs at a junction surface of the low-voltage collector CL and the base B, fluctuates in a manner as will be explained later. The breakdown voltage, at the junction surface of the low-voltage collector CL and the base B, is always lower than a breakdown voltage, at a junction surface of the high-voltage collector CH and the base B.

The base B is formed from a p-type semiconductor area (hereinafter referred to as a p-type area). The base B is connected to a base terminal tB for external connection.

The emitter E is formed from an n-type area, and connected to the base B and an emitter terminal tE for external connection.

In the transistor Q, the low-voltage collector CL, the base B and the emitter E form a first bipolar transistor, while the high-voltage collector CH, the base B and the emitter form a second bipolar transistor.

When a breakdown current flows from the low-voltage collector CL to the base B as a result of a breakdown phenomenon such as an avalanche effect, etc., the base B of the transistor Q keeps holes generated in the base B. The junction surface of the low-voltage collector CL and the base B has such properties that, if the holes kept in the base B increase in number, the impurity density of the base B equivalently increases, equivalently, and its breakdown voltage drops.

If the charge is accumulated into the base B, and a current resulting from the accumulation of the charge flows between the base B and the emitter E, the second bipolar transistor is substantially conducted.

A collector current flowing between the high-voltage collector CH and the emitter E obstructs the accumulation of the holes into the base B, and causes a voltage drop between the base B and the emitter E. The more the collector current increases, the greater the function, that causes a voltage drop between the base B and the emitter E, becomes.

The transistor Q has properties that, if the collector current flows between the high-voltage collector CH and the emitter E, cause a predetermined amount of current to flow between the low-voltage collector CL and the emitter E, until:

(a) the number of holes in the base B is reduced to be equal to or less than a predetermined number, as a result that the base B is grounded or the like;

(b) the second bipolar transistor is OFF, as a result that the voltage between the base B and the emitter E drops because the holes are prevented from being accumulated into the base B by the collector current flowing between the high-voltage collector CH and the emitter E; or

(c) the voltage between the low-voltage collector CL and the base B gets lower than the breakdown voltage of the junction surface thereof. Hereinafter, this predetermined amount of current is referred to as a “holding current”.

The transistor Q may be manufactured in procedures that: the base B is formed by diffusion or ion-implantation of p-type impurities, such as boron, gallium, etc. in the high-voltage collector CH which is formed from an n-type area; and the low-voltage collector CL and the emitter E are formed by diffusion or ion-implantation n-type impurities, such as phosphorus, arsenic, etc. in the base B. Note that the density of the n-type impurities inside the low-voltage collector CL is set to be greater than that of the n-type impurities inside the high-voltage collector CH.

A pn junction, which is formed if the n-type area and the p-type area are connected, has properties that the more the density of the n-type impurities inside this n-type area or the density of the p-type impurities inside this p-type area increases, the more the breakdown voltage of this pn junction decreases. Thus, if the low-voltage collector CL is formed to have the impurity density greater than that of the high-voltage collector CH, the breakdown voltage of the junction surface of the base B and the low-voltage collector CL gets lower than the breakdown voltage of the junction surface of the base and the high-voltage collector CH.

As shown in FIG. 1, the base terminal tB of the transistor Q is connected to the signal-input terminal Ein. The high-voltage collector tCH is connected to the other end of an external load whose one end is connected to the positive electrode of an external direct-current power source, while the low-voltage collector terminal tCL is connected to the bias terminal Ebias through the resistor RB. The emitter terminal tE is connected to the negative electrode of the direct-current power source.

If a source voltage is applied from both electrodes of the direct-current power source, and a bias voltage of positive polarity with respect to the electric potential of the emitter E of the transistor Q is applied to the bias terminal Ebias, the switching circuit of FIG. 1 performs operations, as will be described later.

Let it be assumed that the source voltage and the bias voltage are at a certain level that does not cause a breakdown phenomenon neither on the junction surface of the high-voltage collector CH and the base B nor the junction surface of the low-voltage collector CL and the base B, in a case where the voltage of the base B of the transistor Q is substantially equal to the voltage of the emitter E.

A value of the bias voltage and the resistance value of the resistor RB are set to such a value that a collector current of the second bipolar transistor flows from the bias terminal Ebias through the resistor RB between the low-voltage collector CL and the emitter E, when a later-described control voltage is applied to the base B. The supplier source of the bias voltage may be the same as the above-described direct-current power source connected to the load.

In a case where a source voltage is applied from both electrodes of the direct-current power source and the input-terminal Ein is retained at substantially the same potential as that of the emitter E of the transistor Q, substantially no current flows between the base B and the emitter E. Thus, the first bipolar transistor will be in an OFF state. Because no breakdown phenomenon occurs between the high-voltage collector CH and the base B, substantially no conductivity is made between the high-voltage collector CH and the base B, and no current flows therebetween. Therefore, in the end, substantially no current flows also to the external load.

Let it be assumed that a control voltage of positive polarity with respect to the ground is applied to the input terminal Ein. In this case, a predetermined amount, which is determined depending on the voltage of the base B with respect to the potential of the emitter, of base current flows between the base B and the emitter E of the transistor Q.

By this, the first bipolar transistor is driven, and a collector current flows from the bias terminal Ebias to the emitter E through between the low-voltage collector CL and the emitter E. The size of this collector current is determined based on the size of the base current flowing between the base B and the emitter E, the voltage of the bias terminal Ebias and the resistance value of the resistor RB.

As a result that the base current flows between the base B and the emitter E, the breakdown voltage of the junction surface of the low-voltage collector CL and the base B decreases. If this breakdown voltage decreases to a voltage equal to or lower than the voltage currently occurring between the low-voltage collector CL and the base B, a breakdown phenomenon occurs on the junction surface between the low-voltage collector CL and the base B. Then, holes are accumulated in the base B, and the voltage of the base B with reference to the potential of the emitter E increases, and a current flows between the base B and the emitter E as a result of the accumulation of the holes. As a result of this, the second bipolar transistor is ON, and a current flows from the positive electrode of the direct-current power source to the negative electrode of the direct-current power source through the resistor RL between the high-voltage collector CH and the base B.

Then, the value of the control voltage applied to the input terminal Ein is set to be decreased and the breakdown voltage between the low-voltage collector CL and the base B is set to a value greater than the voltage currently occurring between the low-voltage collector CL and the base B, no breakdown phenomenon occurs on the junction surface of the low-voltage collector CL and the base B. As a result of this, holes are not accumulated in the base B, and the voltage of the base B with reference to the potential of the emitter E decreases, and the second bipolar transistor is OFF (i.e. the high-voltage collector CH and the base B are substantially cut off).

By the above-described operations, in this switching circuit, if the control voltage of positive polarity which is equal to or larger than a predetermined value is applied to the input terminal Ein, the conductivity is made between the high-voltage collector CH and the emitter.

As described above, a breakdown voltage between the low-voltage collector CL and the base B is determined based on the size of the base current and collector current flowing to the low-voltage collector CL. Hence, the minimum value of the voltage to be applied to the input terminal Ein, for making the conductivity between the low-voltage collector CL and the emitter, is determined based on the voltage (i.e. the bias voltage) of the bias terminal Ebias and the resistance value of the resistor RB.

Hence, by changing the bias voltage, the minimum value of the control voltage (i.e. a threshold value of the control voltage) necessary for switching the state of the switching circuit to a state wherein the conductivity is made between the high-voltage collector CH and the emitter E can be set to a predetermined value.

As a result that the breakdown phenomenon occurs between the low-voltage collector CL and the base B of the transistor Q, the breakdown current flowing between the low-voltage collector CL and the base is remarkably multiplied within a short period of time. This breakdown current drives the second bipolar transistor. Therefore, this switching circuit performs switching at a high speed, and there is very little timing gap in the switching.

It is not necessary that the base B of the transistor Q be thinner than the base of a general bipolar transistor, and thus remarkably withstanding the voltage of the base B.

Further, this switching circuit has no Darlington connection circuit, the voltage between the high-voltage collector CH and the emitter E decreases to a voltage level between the collector and emitter of a general bipolar transistor when saturated. Hence, the power loss is very little.

(Second Embodiment: Amplification Circuit)

An amplification circuit according to the second embodiment of this invention will now be explained.

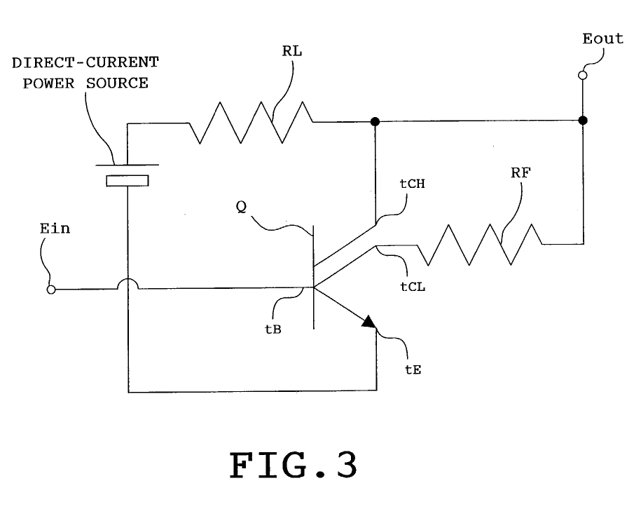

FIG. 3 is a circuitry diagram showing the structure of this amplification circuit.

As shown in FIG. 3, this amplification circuit includes a transistor Q, resistors RF and RF, an input terminal Ein and an output terminal Eout.

The transistor Q is substantially the same as the transistor shown in FIG. 2.

The base terminal tB of the transistor Q is connected to the input terminal Ein. A high-voltage collector terminal tCH is connected to the positive electrode of an external direct-current power source through the resistor RL, while the low-voltage collector terminal tCL is connected to to the high-voltage collector terminal tCH through the resistor RF. The emitter terminal tE is connected to the negative electrode of the direct-current power source. The output terminal Eout is connected to the high-voltage collector terminal tCH.

If a source voltage is applied from both electrodes of the direct-current power source, this amplification circuit performs operations, as will be explained later. Note that the source voltage is a voltage equal to or greater than a breakdown voltage of a junction surface of the low-voltage collector CL and the base B, in a case where the voltage of the base B of the transistor Q is substantially equal to the voltage of the emitter E.

In the case where a source voltage is applied from both electrodes of the direct-current power source and the input terminal Ein is substantially open, no current substantially flows between the base B and the emitter E. Hence, the above-described first bipolar transistor will be in an OFF state.

However, since the low-voltage collector CL is connected to the high-voltage collector CH through the resistor RF, a voltage of equal to or greater than the breakdown voltage is applied thereto. As a result of this, the breakdown phenomenon occurs in the low-voltage collector CL.

As a result of this, a breakdown current flows from the low-voltage collector CL to the base B, and holes are accumulated in the base B. Thus, a collector current flows from the high-voltage collector CH to the emitter E. After this, a voltage drop occurs between both ends of the resistor RL, resulting in a voltage drop of the high-voltage collector CH.

If the voltage of the high-voltage collector CH drops, the voltage of the low-voltage collector CL connected to the high-voltage collector CH through the resistor RF drops as well. If the voltage of the low-voltage collector CL gets lower than the breakdown voltage of the junction surface of the low-voltage collector CL and the base B, no breakdown phenomenon occurs on this junction surface. The accumulation of holes does not happen in the base B, and hence the voltage of the high-voltage collector CH rises. Thus, a breakdown phenomenon occurs in the low-voltage collector CL again.

As a result that an increase or decrease repeatedly occurs in the current flowing between the high-voltage collector CH and the base B transitionally, the size of the current flowing between the high-voltage collector CH and the emitter E (and the resistor RL) is balanced by a predetermined value determined based on the resistance value of the resistor RF.

If a voltage of positive polarity with respect to the ground is applied to the input terminal Ein, a predetermined amount of base current, determined based on the voltage of the base B with respect to the potential of the emitter E, flows between the base B and the emitter E of the transistor Q. By this, holes are accumulated in the base B, and the breakdown voltage of the junction surface of the low-voltage collector CL and the base B drops, and the breakdown current flowing to this junction surface increases. Therefore, the accumulation of the holes in the base B is more accelerated than the case where the input terminal Ein is open, and the voltage of the high-voltage collector CH drops.

However, if the voltage of the high-voltage collector CH drops, the voltage of the low-voltage collector CL drops. As a result of this, no breakdown phenomenon occurs on the junction surface of the low-voltage collector CL and the base B. Therefore, the voltage of the high-voltage collector CH rises, and a breakdown phenomenon occurs in the low-voltage collector CL again.

As a result of this, the size of the current flowing to the high-voltage collector CH and the emitter E (and the resistor RL) is balanced by a predetermined value, which is determined based on the voltage supplied from the input terminal Ein to the base B and the resistance value of the resistor RF. Note that this predetermined value is a value greater than the predetermined value by which the size of the current flowing between the high-voltage collector CH and the emitter E (and the resistor RL) gets balanced in the case where the input terminal Ein is open.

The voltage between both ends of the resistor RL is substantially in proportion to the resistance value of the resistor RL and the size of the current flowing to the resistor RL. Thus, the voltage of the output terminal Eout will be a value, which is obtained by subtracting the value in proportion to the voltage applied to the input terminal Ein from the voltage of the positive electrode of the direct-current power source. That is, the voltage occurring at the output terminal Eout is a voltage which is a resultant voltage amplified substantially by negative phase, after being applied to the input terminal Ein.

By the above-described operations, this amplification circuit amplifies the voltage applied to the input terminal Ein. The amplification factor of this amplification circuit depends on the resistance values of the resistors RL and RF. Thus, at least one of the resistance values of the resistors RL and RF is so selected that the amplification factor of this amplifier will be a predetermined value, thereby forming the structure of this amplification circuit having an arbitrary amplification factor.

As a result that the breakdown phenomenon occurs between the low-voltage collector CL and the base B of the transistor Q, a breakdown current flowing between the low-voltage collector CL and the base B is remarkably multiplied within a short period of time. This breakdown current drives the second bipolar transistor. Hence, this amplification circuit corresponds to the rapid change of the current flowing from the input terminal Ein to the base B, so as to cause a change in the current flowing to the resistor RL and the voltage of the output terminal Eout. That is, this amplification circuit has better frequency characteristics than that including a general bipolar transistor or a Darlington connection circuit.

This breakdown current is generally larger than the current flowing between the first collector and emitter upon supplying of an input signal to the base. Hence, the amplification factor of such an amplification circuit is greater than that including a general bipolar transistor. Negative feedback is done by a feedback circuit network, and hence eliminating the distortion.

It is not necessary that the base B of the transistor Q is thinner than the base of a general bipolar transistor, and thus remarkably withstanding the voltage of the base B.

Further, this amplification circuit does not include Darlington connection circuit, the voltage between the high-voltage collector CH and the emitter E gets lower to a voltage level between the collector and emitter of a general bipolar transistor when saturated. Hence, the power loss is very little.

(Third Embodiment: Constant Voltage Circuit)

A constant-voltage circuit according to the third embodiment of this invention will now be explained.

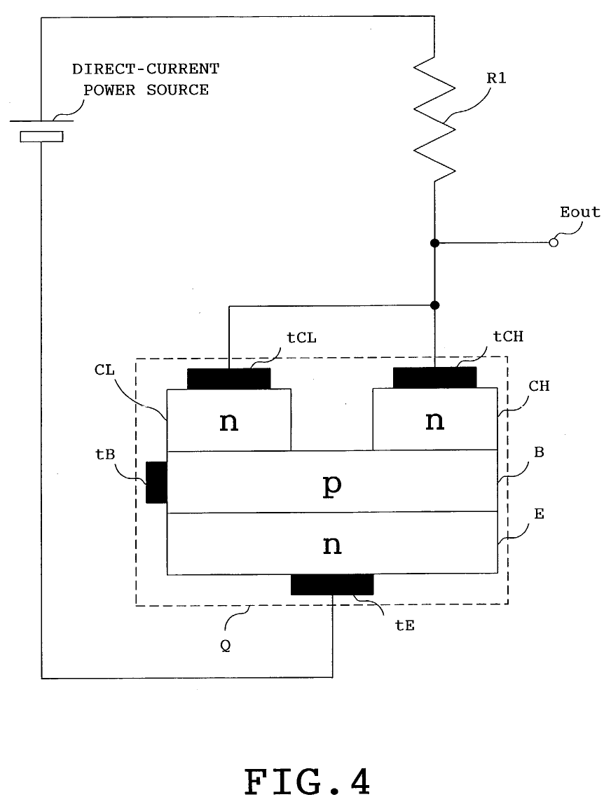

FIG. 4 is a circuitry diagram showing the structure of this constant-voltage circuit.

As shown in FIG. 4, this constant-voltage circuit includes a transistor Q, a resistor R1 and an output terminal Eout.

The transistor Q is substantially the same as the transistor Q shown in FIG. 2.

The low-voltage collector terminal tCL and the high-voltage collector terminal tCH of the transistor Q are connected with each other, and the base terminal tB is open. The high-voltage collector terminal tCH is connected to the positive electrode of an external direct-current power source through the resistor R1, while the emitter terminal tE is connected to the negative electrode of this direct-current power source. The output terminal Eout is connected to the high-voltage collector terminal tCH.

If a source voltage is applied from both electrodes of the direct-current power source, this constant-voltage circuit performs operations, as will be described later, in accordance with the size of the applied source voltage.

If the source voltage is so low that no breakdown phenomenon is caused neither on the junction surface of the low-voltage collector CL and the base B nor on the junction surface of the high-voltage collector CH and the base B, substantially no conductivity is made between the low-voltage collector CL and the base B, and substantially no current flows between the low-voltage collector CL and the base B.

Hence, the second bipolar transistor is in an OFF state, and substantially no current flows between the high-voltage collector CH and the emitter E.

As described above, substantially no conductivity is made between the low-voltage collector CL and the base B. Thus, in the end, substantially no current flows to the emitter E, and substantially no current flows to the resistor R1. Therefore, the voltage of the high-voltage collector tCH and the voltage of the output terminal Eout are substantially equal to the source voltage.

Let it be assumed that the source voltage is substantially high, and a current flows between the base B and the low-voltage collector CL due to the breakdown phenomenon. In this case, as a result that a current flows between the base B and the low-voltage collector CL, holes generated by the breakdown phenomenon are accumulated in the base B, and the potential of the base B rises.

As a result of this, the current flowing between the base B and the low-voltage collector CL drives the second bipolar transistor, and the second bipolar transistor will be in an ON state.

As a result of this, the voltage of the high-voltage collector terminal tCH drops, and the voltage of the low-voltage collector terminal tCL connected to the high-voltage collector terminal tCH drops as well. Therefore, the voltage between the base B and the low-voltage collector CL drops.

If the voltage between the base B and the low-voltage collector CL gets lower than the breakdown voltage of the junction surface of the base B and the low-voltage collector CL, the current flowing from the low-voltage collector CL to the base B is substantially cut off, the second bipolar transistor is OFF, and the voltage of the high-voltage collector terminal tCH turns to rise again.

As a result that an increase or decrease repeatedly occurs in the voltage of the high-voltage collector terminal tCH transitionally, the voltage of the high-voltage collector terminal tCH and the voltage of the output terminal Eout are balanced by a value which is approximately equal to the breakdown voltage of the junction surface of the low-voltage collector CL and the base B.

As explained above, in the constant-voltage circuit shown in FIG. 4, when substantially no current flows from the low-voltage collector CL to the base B, the passage of the current between the high-voltage collector CH and the emitter E is restricted.

On the other hand, if a current substantially flows from the low-voltage collector CL to the base B once, the passage of the current between the high-voltage collector CH and the emitter E and between the low-voltage collector CL and the emitter E is accelerated.

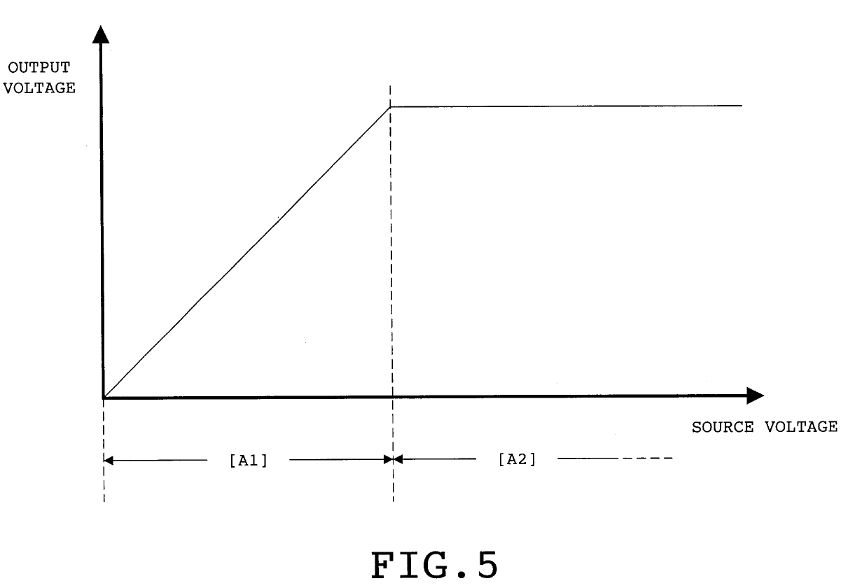

Thus, the constant-voltage circuit of FIG. 4 shows output voltage characteristics shown in FIG. 5. In FIG. 5, the range identified by [A1] shows an area where no breakdown phenomenon occurs on the junction surface of the low-voltage collector CL and the base B, while the range identified by [A2] shows an area where a breakdown phenomenon occurs on the junction surface of the low-voltage collector CL and the base B.

As shown in FIG. 5, in the range [A1], the voltage of the output terminal Eout is approximately equal to the source voltage.

In the range [A2], the voltage of the output terminal Eout is an approximately constant value, and this value is approximately equal to a sum of the breakdown voltage of the junction surface of the low-voltage collector CL and the base B and the voltage between the base B and the emitter E in a state where the breakdown voltage is applied between the low-voltage collector CL and the base B.

In the constant-voltage circuit shown in FIG. 4, in the case where a current substantially flows to the junction surface of the low-voltage collector CL and the base B, the second bipolar transistor is ON.

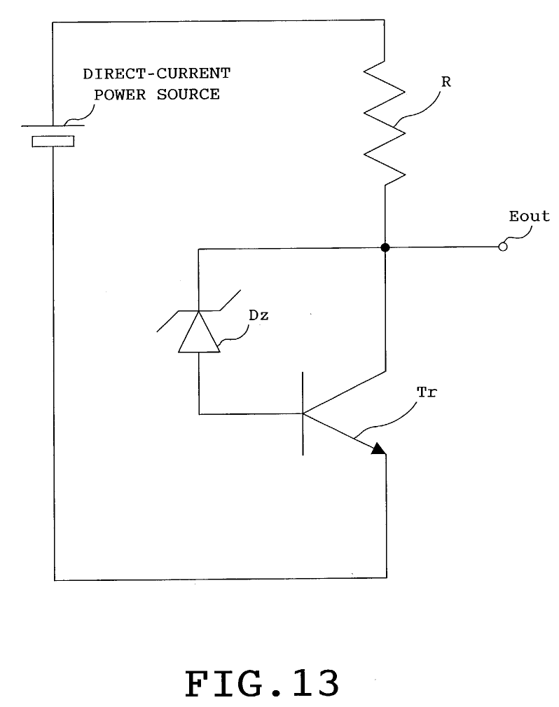

Thus, the voltage of the output terminal Eout does not substantially change in accordance with a change in the size of the current flowing to the junction surface of the low-voltage collector CL and the base B. Hence, as compared to a conventional constant-voltage circuit shown in FIG. 13, for example, the output voltage which is stable with respect to the change in the source voltage can be obtained.

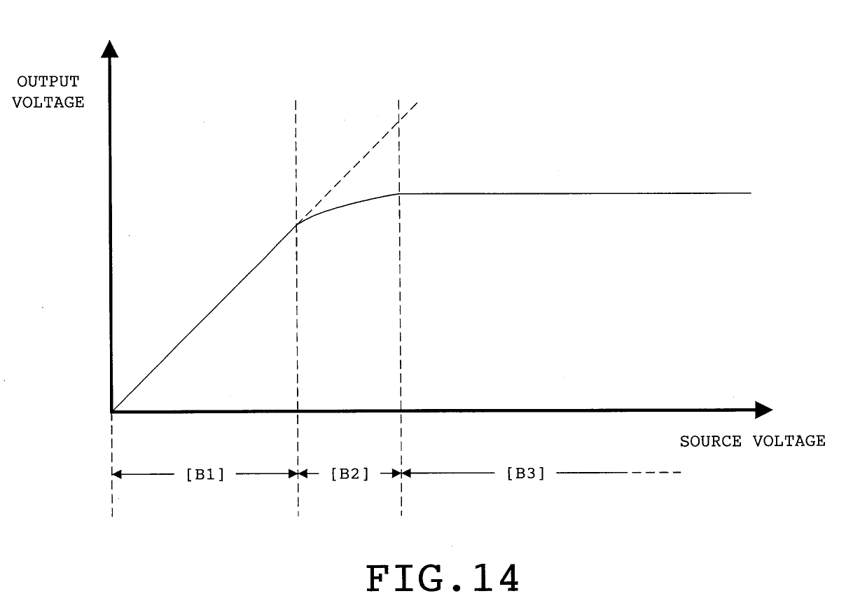

In the constant-voltage circuit shown in FIG. 13, in the case where the source voltage is within a range [B2] shown in FIG. 14, even if a current flows from the cathode of a Zener diode Dz, the size of the current does not cause the bipolar transistor Tr to be saturated. In addition, a phenomenon, in which holes are accumulated in the bipolar transistor Tr does not substantially occur. Hence, in the range [B2], the stability of the output voltage is insufficient.

(Fourth Embodiment: Memory Circuit)

A memory circuit according to the fourth embodiment of the present invention will now be described.

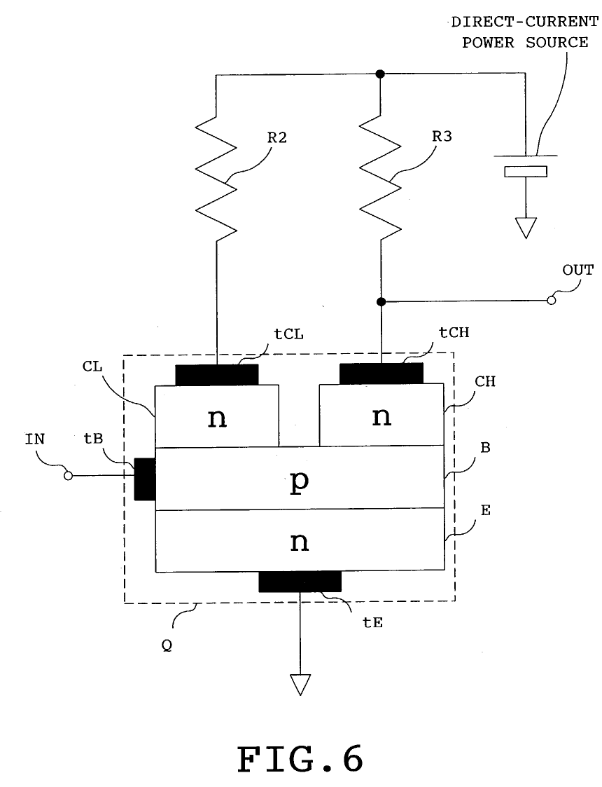

FIG. 6 is a circuitry diagram showing the structure of this memory circuit.

As shown in FIG. 6, this memory circuit includes a transistor Q, resistors R2 and R3, an input terminal IN and an output terminal OUT.

The transistor Q is substantially the same as the transistor shown in FIG. 2.

The resistor R2 is connected between the low-voltage collector terminal tCL and the positive electrode of an external direct-current power source. The resistor R3 is connected between the high-voltage collector terminal tCH and the positive electrode of the direct-current power source. The input terminal IN is connected to the base terminal tB, and the output terminal OUT is connected to the high-voltage collector terminal tCH. The emitter terminal tE is grounded, and the negative electrode of the direct-current power source is grounded as well.

The resistance value of the resistor R2 is selected to such a value that both conditions (1) and (2), as will be described below, are satisfied:

(1) a reverse-direction voltage, which is approximately equal to the maximum voltage not causing breakdown on the junction surface of the low-voltage collector CL and the emitter E, is applied therebetween, in a state wherein a source voltage is supplied from both electrodes of the direct-current power source in a state wherein no current substantially flows to the base terminal tB; and

(2) the size of the current flowing between the low-voltage collector CL and the emitter E is equal to or greater than a holding current, in a state wherein the above-described first bipolar transistor is ON.

The resistance value of the resistor R3 is selected to such a value to prevent that the current flowing between the high-voltage collector CH and the emitter E obstructs the accumulation of holes in the base B so as to cause the first bipolar transistor to be OFF, when a current whose size is equal to or greater than the holding current flows between the low-voltage collector CL and the emitter E.

In this memory circuit, if a source voltage is supplied from both electrodes of the direct-current power source in a state wherein substantially no current flows to the base terminal tB, a voltage which is substantially equal to the source voltage is applied both between the low-voltage collector terminal tCL and the emitter terminal tE and between the high-voltage collector terminal tCH and the emitter terminal tE.

At this time, breakdown occurs neither on the junction surface of the low-voltage collector CL and the base B nor the junction surface of the high-voltage collector CH and the base B.

That is, substantially no current flows to the high-voltage collector CH and the low-voltage collector CL. As a result of this, the potential of the high-voltage collector CH is substantially equal to the direct-current power source. Hence, the potential of the output terminal OUT is approximately equal to the potential of the positive electrode of the direct-current power source.

Next, a sufficiently high voltage (hereinafter referred to as a high-level voltage) is applied to the input terminal IN, such that a base current whose size is large enough to cause the above-described first and second bipolar transistors to be saturated is supplied from the input terminal IN to the base B. Then, as a result that the first and second bipolar transistors are saturated, the potential of the high-voltage collector CH and the potential of the low-voltage collector CL will approximately be equal to the potential of the emitter. As a result of this, the potential of the high-voltage collector CH is approximately equal to the ground potential, and hence the potential of the output terminal OUT is also equal to the ground potential.

Holes are accumulated in the base B, and resulting in that the potential of the base B rises, and breakdown occurs on the junction surface of the low-voltage collector CL and the base B.

Next, the supplying of the above-described base current from the input terminal IN is substantially cut off.

At this time, breakdown occurs on the junction surface of the low-voltage collector CL and the base B. Thus, a holding current continues to be flowing between the low-voltage collector CL and the emitter. The holding current drives the second bipolar transistor.

Thus, the second bipolar transistor keeps to be in an ON state, even if the current supplied from the input terminal IN to the base terminal tB is substantially cut off. Hence, the potential of the output terminal OUT keeps to be approximately equal to the ground potential.

Next, if a voltage (hereinafter referred to as a low-level voltage) which is low enough to cause the first and second bipolar transistors to be in an OFF state is applied to the input terminal IN (e.g. grounded), the potential of the high-voltage collector CH is substantially equal to the potential of the positive electrode of the direct-current power source. The potential of the output terminal OUT is approximately equal to the potential of the positive electrode of the direct-current power source.

The holes accumulated in the base B are recombined with electrons upon drop of the voltage of the base B to a low-level voltage, and are reduced so as to be equal to or less than the above-described predetermined amount. As a result of this, the breakdown voltage of the junction surface of the low-voltage collector CL and the base B rises, and the holding current will not substantially be flowing. Thus, even if the input-terminal IN is no longer grounded and substantially no current is supplied to the base terminal tB, the first and second bipolar transistors continuously keep to be in an OFF state.

As a result of this, this memory circuit returns to be in a state substantially same as the primary state wherein the source voltage is supplied to this memory circuit. Hence, the potential of the output terminal OUT is kept approximately the same as the potential of the positive electrode of the direct-current power source.

As described above, in this memory circuit, if a high-level voltage is applied to the input terminal IN, the voltage of the output terminal OUT is kept approximately to the ground potential upon application of a high-level voltage to the input terminal IN. Even after the application of the high-level voltage is no longer performed, this memory circuit operates in such a state that the voltage of the output terminal OUT is kept approximately to the ground potential, until a low-level voltage is applied to the input terminal IN.

If a low-level voltage is applied to the input terminal IN, the voltage of the output terminal OUT is set approximately equal to the potential of the positive electrode of the direct-current power source. Even if the application of the low-level voltage stops, this memory circuit operates in a state where the voltage of the output terminal OUT is kept approximately the same as the potential of the positive electrode of the direct-current power source, until a high-level voltage is applied again to the input terminal IN.

Hence, the voltage of the output terminal OUT shows whether the voltage most recently applied to the input terminal IN is a high-level voltage or a low-level voltage. That is, this memory circuit shown in FIG. 6 stores binary data of the voltage most recently applied to the input terminal IN.

(Fifth Embodiment: Oscillation Circuit)

An oscillation circuit according to the fifth embodiment of the present invention will now be explained.

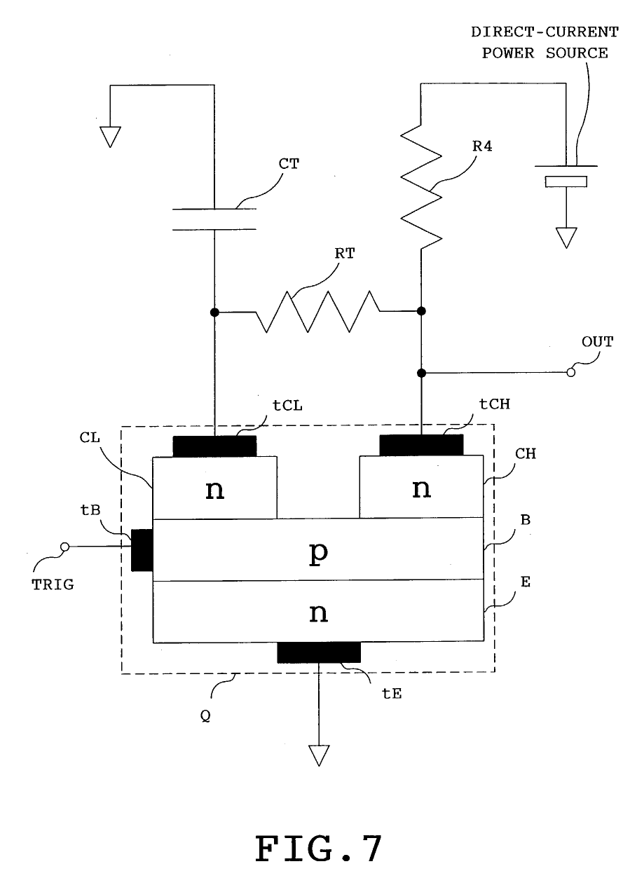

FIG. 7 is a circuitry diagram showing the structure of this oscillation circuit.

As shown in FIG. 7, this memory circuit includes a transistor Q, resistors R4 and RT, a capacitor CT, a trigger input terminal TRIG and an output terminal OUT.

The transistor Q is substantially the same as the transistor shown in FIG. 2.

The resistor R4 is connected between the high-voltage collector terminal tCH and the positive electrode of an external direct-current power source. The resistor RT is connected between the high-voltage collector terminal tCH and the low-voltage collector tCL. One end of the capacitor CT is connected to the low-voltage collector terminal tCL, and the other end thereof is grounded. The trigger input terminal TRIG is connected to the base terminal tB, and the output terminal OUT is connected to the high-voltage collector terminal tCH. The emitter terminal tE is grounded, and the negative electrode of the direct-current power source is grounded as well.

In this oscillation circuit, if a source voltage is supplied from both electrodes of the direct-current power source in a state wherein the above-described low-level voltage is applied to the base terminal tB, the first and second bipolar transistors are OFF, and the potential of the high-voltage collector CH and the potential of the output terminal OUT are substantially equal to the potential of the positive electrode of the direct-current power source.

The voltage generated at the output terminal OUT is applied to both ends of a series circuit including the resistor RT and the capacitor CT. Hence, the capacitor CT is charged by the current flowing to the series circuit. If this charge of the capacitor CT is substantially completed, the voltage of the connection point of the capacitor CT and the resistor RT and the voltage of the low-voltage collector terminal tCL are substantially equal to the voltage of the output terminal OUT. Thus, if the voltage of the high-voltage collector CH changes, this change is transmitted to the low-voltage collector tCL after being delayed by the capacitor CT and the resistor RT.

Because the low-level voltage is applied to the base B, the potential of the base B does not substantially rise. Thus, holes are not substantially accumulated in the base, and hence the breakdown voltage of the junction surface of the low-voltage collector CL and the base B does not decrease, so that no breakdown occurs on the junction surface.

Next, the low-level voltage is no longer applied to the base terminal tB, and the base terminal tB is open.

Then, as a result that holes are accumulated in the base B and the potential of the base B rises, the breakdown voltage of the junction surface of the low-voltage collector CL and the base B decreases, so that breakdown occurs on the junction surface. As a result of this, a current whose size is equal to or larger than the holding current flows from the low-voltage collector CL to the base B, and the second bipolar transistor is ONN by this current, and the voltage of the output terminal OUT is approximately 0.

Hence, the capacitor CT makes a current flow to the resistor RT so as to discharge electricity therefrom, and the voltage of the connection point of the capacitor CT and the resistor RT and the voltage of the low-voltage collector terminal tCL begin to decrease.

A holding current further continues to flow between the low-voltage collector CL and the base B, between which a current whose size is equal to or larger than the holding current has once flowed, and the second bipolar transistor continues to be driven by this holding current.

By this holding current, holes are further accumulated in the base B and the potential of the base B rises. As a result of this, the breakdown voltage of the junction surface of the low-voltage collector CL and the base B drops. Thus, the second bipolar transistor does not turn to be in an OFF state, right after it is ON. The time required for shifting the ON state to OFF state is substantially in proportion to a product of: an amount of a drop in the breakdown voltage of the junction surface of the low-voltage collector CL and the base B; and a product of the electrostatic capacity of the capacitor CT and the resistance value of the resistor RT (i.e. a time constant of the capacitor CT and the resistor RT). This drop is due to an increase in the holes of the base B.

As a result that the voltage of the low-voltage collector terminal tCL further decreases, the second bipolar transistor is OFF if substantially no holding current flows between the low-voltage collector CL and the base B. Hence, the voltage of the output terminal OUT is substantially equal to the voltage of the positive electrode of the direct-current power source.

Then, the capacitor CT is charged with electricity again, and the voltage of the low-voltage collector terminal tCL turns to rise. Until a breakdown phenomenon occurs again on the junction surface of the low-voltage collector CL and the base B, the voltage of the low-voltage collector terminal tCL continues to rise.

Even after the voltage of the low-voltage collector terminal tCL begins to rise, substantially no holding current flows between the low-voltage collector CL and the base B. Thus, the accumulation of the holes in the base B does not substantially progress, and the already-accumulated holes travel to the emitter E and are reduced by getting recombined with majority carriers in the emitter E. Thus, the breakdown voltage of the junction surface of the low-voltage collector CL and the base B rises.

Thus, the second bipolar transistor does not turn to be in an ON state, right after it is OFF. The time required for shifting the OFF state to the ON state is substantially in proportion to a product of a time constant of the capacitor CT and the resistor RT and an amount of rise in the breakdown voltage of the junction surface of the low-voltage collector CL and the base B. This rise is due to a reduction in the holes in the base B.

The output terminal OUT alternately generates a voltage, which is approximately equal to the voltage of the positive electrode of the direct-current power source, and a voltage, which is approximately equal to 0. That is, in this oscillation circuit shown in FIG. 7, the voltage generated at the output terminal OUT is oscillated.

The cycle of this oscillation is substantially proportion to a product of the time constant of the capacitor CT and the resistor RT and an amount of a change in the breakdown voltage on the junction surface of the low-voltage collector CT and the base B. This change is due to an increase or reduction in the electric charge accumulated in the base B.

The switching circuit, switching circuit, amplification circuit and bipolar transistors of the embodiments of this invention are not limited to the above.

For example, it is not necessary that the conductivity types of the low-voltage collector CL, the high-voltage collector CH, the base B and the emitter E of the transistor Q be of an n-type, n-type, p-type and n-type, respectively, in the switching circuit of FIG. 1, the amplification circuit of FIG. 3, the constant-voltage circuit of FIG. 4, the memory circuit of FIG. 6 or the oscillation circuit of FIG. 7, Thus, their conductivity types may be of a p-type, p-type, n-type and p-type, respectively.

Note, in the case where the conductivity types of the low-voltage collector CL, high-voltage collector CH, base B and emitter E of the transistor are p-type, p-type, n-type and p-type, respectively, the positive electrode of the direct-current power source is connected to the emitter terminal tE, while the negative electrode thereof is connected to one of both ends of the resistor RL which is not connected to the transistor Q, in both of the switching circuit of FIG. 1 and the amplification circuit of FIG. 3.

In the case where the conductivity types of the low-voltage collector CL, high-voltage collector CH, base B and emitter E of the transistor are p-type, p-type, n-type and p-type, the positive electrode of the direct-current power source is connected to the emitter terminal tE, and the negative electrode of the direct-current power source is connected to the high-voltage collector terminal tCH through the resistor R1, in the constant-voltage circuit of FIG. 4.

In the case where the conductivity types of the low-voltage collector CL, high-voltage collector CH, base B and emitter E of the transistor Q are p-type, n-type, n-type and p-type, respectively, the positive electrode of the direct-current power source is grounded, while the negative electrode of the direct-current power source is connected to the low-voltage collector terminal tCL through the resistor R2 and to the high-voltage collector terminal tCH through the resistor R3, in the memory circuit of FIG. 6.

In the case where the conductivity types of the low-voltage collector CL, high-voltage collector CH, base B and emitter E of the transistor Q are p-type, p-type, n-type and p-type, respectively, the positive electrode of the direct-current power source is grounded, while the negative electrode of the direct-current power source is connected to the high-voltage collector terminal tCH through the resistor R4, in the oscillation circuit of FIG. 7.

Operations of the transistor, wherein the conductivity types of the low-voltage collector CL, high-voltage collector CH, base B and emitter E are p-type, p-type, n-type and p-type, respectively, are substantially same as operations of the transistor Q, wherein the conductivity types of the low-voltage collector CL, high-voltage collector CH, base B and emitter E are n-type, n-type, p-type and n-type, respectively. This is the case except: that the direction of the current flowing between the external of the transistor Q and the low-voltage collector CL, high-voltage collector CH, base B and emitter E gets reversed; and that the carries accumulated in the base B are electrons instead of holes.

The direction of the current flowing between the external of the transistor Q and the low-voltage collector CL, high-voltage collector CH, base B and emitter E gets reversed. Hence, in the case where the conductivity types of the high-voltage collector CH, base B and emitter are p-type, p-type, n-type and p-type, respectively, the voltage to be applied to the input terminal Ein and the bias terminal Ebias needs to be negative polarity with respect to the potential of the emitter, in order to control ON and OFF between the low-voltage collector CL and emitter E of the transistor Q in the switching circuit of FIG. 1. In the amplification circuit of FIG. 3, to amplify the voltage to be applied to the input terminal Ein, the voltage to be applied to the input terminal Ein needs to be negative polarity with respect to the potential of the emitter E. In the memory circuit of FIG. 6 or the oscillation circuit of FIG. 7, let it be assumed that a high-level signal to be applied to the input terminal IN (or the trigger input terminal TRIG) is a low enough voltage for causing the base current, which is sufficient enough for the first and second bipolar transistors to be saturated, to flow to the base B. The low-level voltage is a voltage which is high enough to cause the first and second bipolar transistors to be in an OFF state.

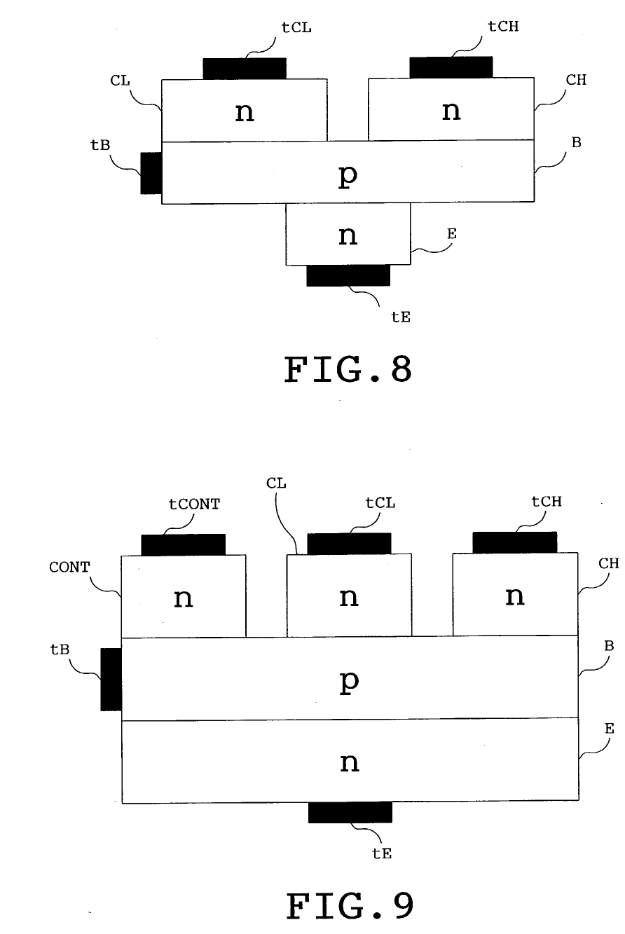

In the transistor Q, the area of the junction surface between the base B and the emitter E may be smaller than the area of the junction surface between the base B and the high-voltage connector CH, as shown in FIG. 8.

The smaller the area of the junction surface between the base B and the emitter E becomes, the larger the input impedance of the base B of the transistor Q becomes. Thus, the input impedance of the base B of the transistor is larger in the case where the area of the junction surface between the base B and the emitter E is smaller than the area of the junction surface of the base B and the high-voltage collector CH, as compared to the case where the area of the junction surface between the base B and the emitter is equal to or larger than the area of the junction surface between the base B and the high-voltage collector CH.

Hence, the input impedance of the switching circuit of FIG. 1 which includes the transistor Q of FIG. 8 gets larger than the input impedance of the switching circuit of FIG. 1 which includes the transistor Q of FIG. 2. Similarly, the input impedance of the amplification circuit of FIG. 3 which includes the transistor Q of FIG. 8 gets larger than the input impedance of the amplification circuit of FIG. 3 which includes the transistor Q of FIG. 2.

The conventional transistor for high power application has a drawback that its current amplification factor is low and its frequency characteristics are not desirable. In contrast to this, the transistor Q shown in FIG. 8 can easily be controlled as if it was a transistor for low power application, even through it is a transistor for high power application, and hence being able to be widely used for power controlling.

Generally, the larger the area of the junction surface between the base and the emitter, the greater the current amplification factor of bipolar transistors. The ratio of the size of the breakdown current flowing between the low-voltage collector CL and the base B to the size of the base current of the transistor Q is larger than the current amplification factor of the general bipolar transistors.

There are cases where: (A) a predetermined base current is supplied to the base B of the transistor Q of an embodiment of this invention; and (B) the same amount of base current as that of the base current of the transistor Q is supplied to a bipolar transistor having the same area of the junction surface between the base and the emitter as the area of the junction surface of the base B and the emitter of the transistor Q. In the case where the above cases of (A) and (B) are compared, the breakdown current, flowing between the low-voltage collector CL and the base B of the transistor Q in the case (A), is greater than the collector current flowing to the collector of the bipolar transistor in the case (B).

The minority carriers flowing from the emitter E to the base B widely diffuse, and are absorbed as collector current flowing to the high-voltage collector CH or low-voltage collector CL.

The smaller the junction capacity of the capacitor included in the junction surface between the base B and the high-voltage collector CH, the better the frequency characteristics of the transistor Q (i.e. the transition frequency gets higher). The smaller the area of the junction surface between the base B and the high-voltage collector CH becomes, the smaller the junction capacity of the capacitor included in this junction surface becomes as well.

In the case where the transistor Q, whose junction surface between the base B and the high-voltage collector CH is smaller than the junction surface between the base B and the emitter E, as shown in FIG. 2, is compared to the transistor Q of FIG. 8, the frequency characteristics of the transistor Q of FIG. 2 are more desirable than that of the transistor Q of FIG. 8, under the assumption that both transistors Q have the same area of the junction surface between the base B and the emitter E.

The switching speed of the switching circuit of FIG. 1 which includes the transistor Q of FIG. 2 is faster than the switching speed of the switching circuit of FIG. 1 which includes the transistor Q of FIG. 8. The frequency characteristics of the amplification circuit of FIG. 3 which includes the transistor Q of FIG. 2 are more preferable than the frequency characteristics of the amplification circuit of FIG. 3 which includes the transistor Q of FIG. 8.

The transistor Q included in the constant-voltage circuit of FIG. 4, the transistor Q in the memory circuit of FIG. 6 or the transistor Q in the oscillation circuit of FIG. 7 may include a control layer CONT for controlling the quantity of the holes or electrons accumulated in the base B, as shown in FIG. 9.

The control layer CONT is formed from a semiconductor area which is of the same impurity type as that of the low-voltage collector CL and high-voltage collector CH (i.e., in the case where the low-voltage collector CL and the high-voltage collector CH are formed of an n-type area, the control layer CONT is formed from an n-type area). The control layer CONT is connected to the base B without directly being connected to the low-voltage collector CL and the high-voltage collector CH. The breakdown voltage of the junction surface of the control layer CONT and the base B is higher than the breakdown voltage of the junction surface of the low-voltage collector CL and the base B, and the control layer CONT is connected to a control layer tCONT for external connection.

The control layer CONT may be formed by diffusion or ion-implantation of n-type impurities (or p-type impurities) in the base B which is formed from a p-type area (or an n-type area). Note that the density of the n-type impurities (or the p-type impurities) inside the control layer CONT is to be set lower than that of the n-type impurities (or the p-type impurities) inside the low-voltage collector CL.

If a voltage, for causing a breakdown phenomenon on the junction surface of the control layer CONT and the base B, is applied to the control layer tCONT, the majority carriers (e.g. or holes, if the base B is formed from a p-type area) in the conductivity type semiconductor of the base B are accumulated in the base B.

If a voltage, for causing the junction surface between the control layer CONT and the base B to be forward-biased, is applied to the control layer tCONT, the majority carriers accumulated in the base B are recombined with the majority carriers (e.g. electrons as majority carriers in an n-type area, if the base B is formed from a p-type area), which are supplied from the control layer CONT and included in the control layer CONT, so as to be reduced.

Hence, the quantity of the majority carriers accumulated in the base B is controlled in accordance with the voltage applied to the control layer CONT. Specifically, for example, rectangular waves vibrating between above-described high-level voltage and low-level voltage are applied to the control layer CONT, and the duty ratio of the rectangular waves are changed, thereby controlling the quantity of the majority carriers accumulated in the base B.

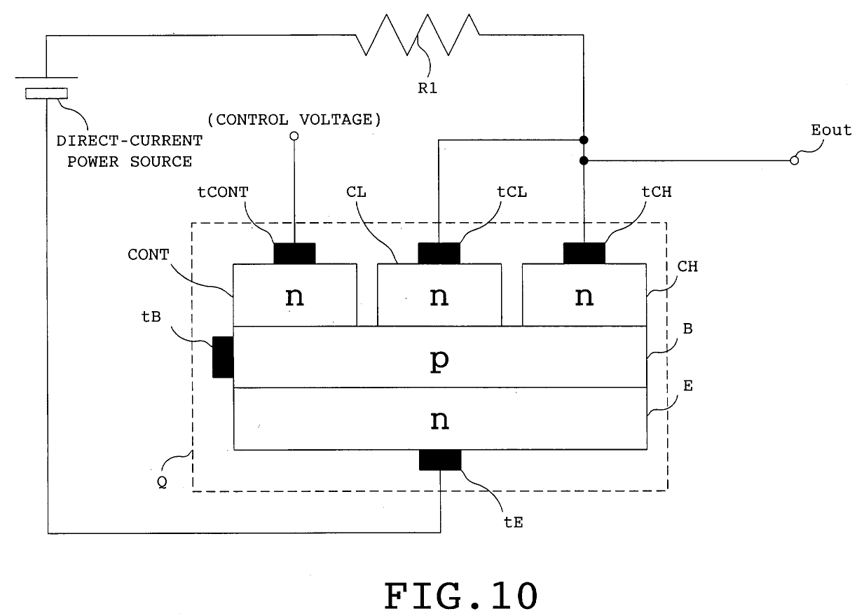

In the case where there is formed a constant-voltage circuit which is substantially the same as the constant-voltage circuit of FIG. 4, using the transistor Q having the structure shown in FIG. 9 (i.e. in the case where there is formed the constant-voltage circuit shown in FIG. 10, for example), if the voltage (control voltage) to be applied to the control layer tCONT is changed, the voltage generated at the output terminal Eout is controlled in accordance with the change.

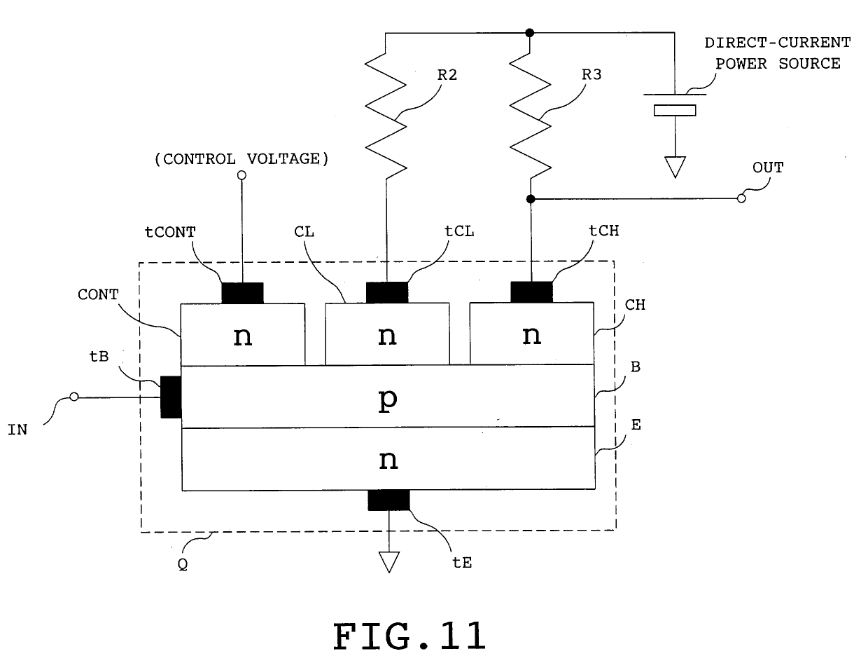

In the case where there is formed a memory circuit which is substantially the same as the memory circuit of FIG. 6 using the transistor having the structure shown in FIG. 9 (i.e. in the case where there is formed the memory circuit shown in FIG. 11, for example), if the control voltage to be applied to the control layer tCONT is changed, a threshold value of a voltage at the input terminal IN (i.e. such a value of the voltage at the input terminal IN that causes a change in the logical state of the output terminal OUT) is controlled in accordance with the change in the control voltage.

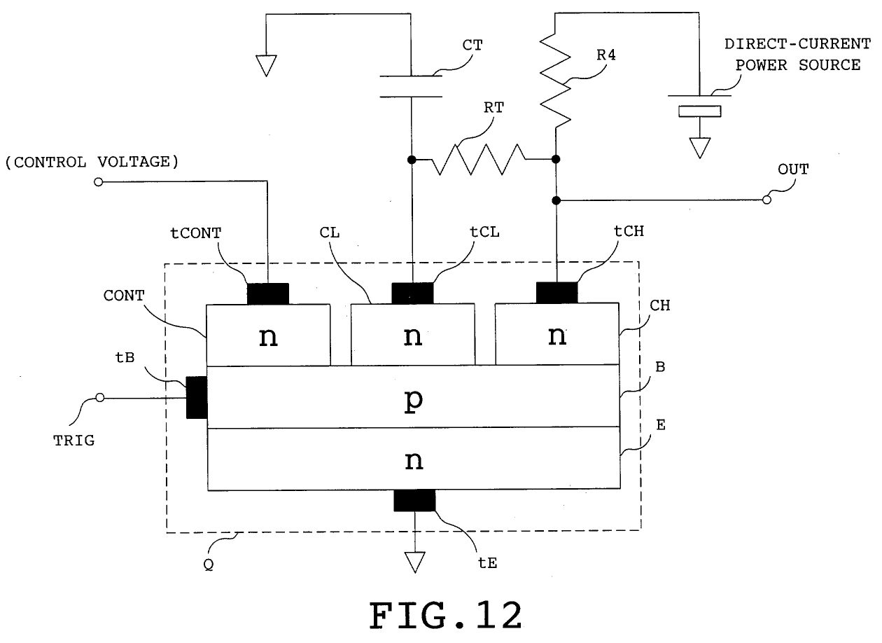

In the case where there is formed an oscillation circuit which is substantially the same as the oscillation circuit of FIG. 7 is formed using the transistor Q having the structure shown in FIG. 9 (i.e. in the case where there is formed the oscillation circuit shown in FIG. 12, for example), if the control voltage to be applied to the control layer tCONT is changed, the value of the oscillation period of the voltage generated at the output terminal OUT is controlled in accordance with the change in the control voltage.

Each of the constant-voltage circuit shown in FIG. 10, the memory circuit shown in FIG. 11 and the oscillation circuit shown in FIG. 12 includes signal source supplying the control layer tCONT with a control voltage, as illustrated.

This invention is not limited to the above-described first to fifth embodiments, and various modifications and applications can be made thereonto.

As explained above, according to this invention, there are realized a bipolar transistor circuit which can withstand a high voltage, perform switching at a high speed with very little timing gap, performs amplification with a low level of distortion or a high amplification factor, or operate with little power loss, and also a usage method of a bipolar transistor for realizing such a bipolar transistor circuit.

According to this invention, there are realized a bipolar transistor circuit, which performs oscillation or stores data and can be easily formed with a small number of transistors and which is suitable for high density integration, and a usage method of realizing a bipolar transistor for such a bipolar transistor circuit.

According to this invention, there are realized a bipolar transistor which sufficiently stabilizes the output voltage and supplies high power, and a usage method of a bipolar transistor for realizing such a bipolar transistor circuit.

The patent application claims the Paris Convention Priority based on Japanese Patent Application No. 2000-272458 filed with the Japan Patent Office on Sep. 8, 2000, the complete disclosure of which is hereby incorporated by reference.

1. A bipolar transistor circuit which includes a structure (Q) for performing switching while withstanding a high voltage or performing amplification with a high amplification factor, reducing power loss, performing oscillation with a simple structure or storing data, or stabilizing an output voltage and supplying large power.

2. The bipolar transistor circuit according to claim 1, wherein said bipolar transistor circuit includes a current path (CH, E), determines, when a trigger signal and a bias signal are supplied to said bipolar transistor circuit, whether intensity of said trigger signal has reached a threshold value determined based on intensity of the bias signal, and controls opening and closing of said current path in accordance with a result of determination, said bipolar transistor including
a bipolar transistor (Q) which comprises: a first conductivity-type emitter (E); a second conductivity-type base (B) connected to said emitter; a first conductivity-type first collector (CH) connected to said base; and a first conductivity-type second collector (CL) connected to said base, and wherein a breakdown voltage of a junction surface of said base and said second collector is lower than a breakdown voltage of a junction surface of said base and said first collector, and
wherein
said emitter of said bipolar transistor forms one end of said current path,
said first collector of said bipolar transistor forms other end of said current path,
said bipolar transistor
causes a current to flow between said emitter and said base, when said trigger signal is supplied to said base,
causes the breakdown voltage of the junction surface of said second collector and said base to be changed in accordance with size of the current flowing between said emitter and said base,
causes, when a voltage of the junction surface of the second collector and said base reaches the breakdown voltage as a result that the bias signal is supplied to said second collector and said trigger signal is supplied to said base, breakdown to occur on the junction surface, thereby conductivity is made on the junction surface and a breakdown current flows on the junction surface, and
causes conductivity to be made between said first collector and said emitter, when the breakdown voltage flows.

3. The bipolar transistor circuit according to claim 2, wherein
an area of the junction surface of the base and first collector of said bipolar transistor is smaller than an area of the junction surface of said base and said emitter.

4. The bipolar transistor circuit according to claim 2, wherein
an area of the junction surface of said base and emitter of said bipolar transistor is smaller than an area of the junction surface of said base and said first collector.

5. The bipolar transistor circuit according to claim 1, wherein said bipolar transistor circuit includes a current path (CH, E), and causes an output current representing a signal which is an amplified input signal supplied to said bipolar transistor circuit to be flowing to said current path, and said bipolar transistor comprising:
a bipolar transistor which comprises a first conductivity-type emitter (E), a second conductivity-type base (B) connected to said emitter, a first conductivity-type collector (CH) connected to said base, and a first conductivity-type second collector (CL) connected to said base, and wherein a breakdown voltage of the unction surface of said base and said first collector is higher than a breakdown voltage of the junction surface of said base and said second collector; and
a feedback circuit network (RF) which is connected between said first collector and said second collector of said bipolar transistor, and
wherein
said emitter of said bipolar transistor forms one end of said current path,
said first collector of said bipolar transistor forms other end of said current path,
a breakdown current flows to the junction surface of the second collector and base of said bipolar transistor,
said output current whose size is determined based on a size of the breakdown current flows to the junction surface of the first collector and base of said bipolar transistor, when the breakdown current flows to the junction surface of the second collector and base of said bipolar transistor, and
the size of the breakdown current is determined based on intensity of the input signal supplied to the base of said bipolar transistor and intensity of a feedback signal to be supplied to said second collector of said bipolar transistor through said feedback circuit network.

6. The bipolar transistor circuit according to claim 5, wherein
an area of the junction surface of said base and first collector of said bipolar transistor is smaller than an area of the junction surface of said base and said emitter.

7. The bipolar transistor circuit according to claim 5, wherein
an area of the junction surface of said base and emitter of said bipolar transistor is smaller than an area of the junction surface of the base and said first collector.

8. The bipolar transistor circuit according to claim 1, wherein said bipolar transistor circuit includes a pair of ends, and supplies substantially a constant stabilized voltage from said pair of ends when a voltage is applied through a load (R1) which is cascaded to said bipolar transistor circuit, and said bipolar transistor including
a bipolar transistor (Q) which comprises a first conductivity-type emitter (E), a second conductivity-type base (B) connected to said emitter, a first conductivity-type first collector (CH) connected to said base, and a first conductivity-type second collector (CL) connected to said base, and wherein a breakdown voltage of a junction surface of said base and said first collector is higher than a breakdown voltage of a junction surface of said base and said second collector, and
wherein:
said emitter forms one of said pair of ends;
said first and second collectors are connected with each other so as to form other one of said pair of ends; and
the stabilized voltage is supplied from said pair of ends, when a voltage for causing a reverse voltage equal to or greater than the breakdown voltage of the unction surface of said base and said second collector to be applied to the junction surface of said base and second collector of said bipolar transistor is applied to said pair of ends.

9. The bipolar transistor circuit according to claim 8, wherein:
said bipolar transistor includes a first conductivity-type control layer (CONT) which is connected to said base; and
the breakdown voltage of the junction surface of said base and said control layer is greater than the breakdown voltage of the junction surface of said base and said second collector.

10. The bipolar transistor circuit according to claim 1, comprising:
a bipolar transistor which includes a first conductivity-type emitter (E), a second conductivity-type base (B) connected to said emitter, a first conductivity-type first collector (CH) connected to said base, and a first conductivity-type second collector (CL) connected to said base, and wherein a breakdown voltage of a junction surface of said base and said first collector is greater than a breakdown voltage of a junction surface of said base and said second collector;
a circuit network (R2) which applies a reverse voltage which is lower than the breakdown voltage of the junction surface to the junction surface of said base and second collector of said bipolar transistor, when a bias voltage is externally applied; and
a load (R3) which is cascaded to a section whose ends are said first collector and emitter of said bipolar transistor, and
wherein a source voltage is applied to both ends of a series circuit including said section and said load, the bias voltage is applied to said circuit network, and a signal representing a size of a current flowing to the series circuit is supplied as an output signal representing a value represented by a latest input signal applied to said base, when the input signal is applied to said base of said bipolar transistor.

11. The bipolar transistor circuit according to claim 10, wherein:
said bipolar transistor includes a first conductivity-type control layer (CONT) connected to said base; and
the breakdown voltage of the junction surface of said base and said control layer is greater than the breakdown voltage of the junction surface of said base and said second collector.

12. The bipolar transistor circuit according to claim 1, comprising:
a bipolar transistor comprising a first conductivity-type emitter (E), a second conductivity-type base (B) connected to said emitter, a first conductivity-type first collector (CH) connected to said base, and a first conductivity-type second collector (CL) connected to said base, and wherein a breakdown voltage of a junction surface of said base and said first collector is greater than a breakdown voltage of a junction surface of said base and said second collector; and
a feedback circuit network (CT, RT) which applies a voltage representing a substantially delayed signal representing a voltage of said first collector of said bipolar transistor, to the junction surface of said base and second collector of said bipolar transistor, and
wherein said bipolar transistor circuit outputs an oscillation signal representing a size of a current flowing to said first collector of said bipolar transistor.

13. The bipolar transistor circuit according to claim 12, wherein said bipolar transistor circuit outputs or stops outputting the oscillation signal, when a trigger signal for setting said bipolar transistor to be ON and OFF is supplied to said base of said bipolar transistor, in accordance with the trigger signal.

14. The bipolar transistor according to claim 12, wherein:
said bipolar transistor includes a first conductivity-type control layer (CONT) connected to said based; and
the breakdown voltage of the junction surface of said base and said control layer is greater than the breakdown voltage of the junction surface of said base and said second collector.

15. A usage method of a bipolar transistor and including a step of realizing
a bipolar transistor circuit which performs switching while withstanding a high voltage or performs amplification with a high amplification factor,
a bipolar transistor circuit which operates with little power loss,
a bipolar transistor circuit which performs oscillation with a simple structure or stores data, or
a bipolar transistor circuit which stabilizes an output voltage and performs supplying of large power.

16. The usage method according to claim 15, wherein said usage method is for a bipolar transistor, comprising a first conductivity-type emitter, a second conductivity-type base connected to said emitter, a first conductivity-type first collector connected to said base, and a first conductivity-type second collector connected to said base, and said method is for controlling conductivity and non-conductivity between said emitter and first collector of said bipolar transistor, and said method comprising:
changing a breakdown voltage of a junction surface of said first collector and said base, in accordance with a size of a current flowing between said emitter and said second collector and a size of a current flowing between said emitter and said base; and
supplying said base with a trigger signal and setting a voltage of the junction surface of said first collector and said base to reach the breakdown voltage, and causing breakdown on said junction surface so as to make conductivity on the junction surface and conductivity between said emitter and said first collector.

17. The usage method according to claim 16, wherein
an area of the junction surface of said base and emitter of said bipolar transistor is smaller than an area of the junction surface of said base and said first collector.

18. The usage method according to claim 16, further comprising
controlling a size of a breakdown current flowing to the junction surface of said first collector and said base, by controlling the size of the current flowing between an external section and said base and the size of the current flowing between an external section and said second collector.

19. The usage method according to claim 16, wherein
the breakdown voltage of the junction surface of said first collector and said base and the breakdown voltage of the junction surface of said second collector and said base are different from each other.

20. The usage method according to claim 15, wherein said method is for a bipolar transistor comprising a first conductivity-type emitter, a second conductivity-type base connected to said emitter, a first conductivity-type first collector connected to said base, and a first conductivity-type second collector connected to said base, and said method is for changing a breakdown voltage of a junction surface of said first collector and base of said bipolar transistor, and said method comprising
changing the breakdown voltage of the junction surface of said first collector and said base, by changing a size of a current flowing between said emitter and said second collector and a size of a current flowing between said emitter and said base.

21. The usage method according to claim 20, comprising
controlling a size of a breakdown current flowing to the junction surface of said first collector and said base, by controlling a size of a current flowing between an external section and said base and a size of a current flowing between an external section and said second collector.

22. The usage method according to claim 20, wherein
an area of a junction surface of said base and emitter of said bipolar transistor is smaller than an area of the junction surface of said base and said first collector.

23. The usage method according to claim 20, wherein
the breakdown voltage of the junction surface of said first collector and said base and a breakdown voltage of a junction surface of said second collector and said base are different from each other.

24. The usage method according to claim 15, comprising:
forming a second conductivity-type base connected to a first conductivity-type emitter;
forming a first conductivity-type first collector connected to said base; and
forming a first conductivity-type second collector which is connected to said base, and wherein a breakdown voltage of a junction surface to said base is lower than a breakdown voltage of a junction surface of said base and said first collector.

25. The usage method according to claim 24, wherein
an area of the junction surface of said base and said first collector is smaller than an area of a junction surface of said base and said emitter.

26. The usage method according to claim 24, wherein
an area of a junction surface of said base and said emitter is smaller than an area of the junction surface of said base and said first collector.

27. The usage method according to claim 24, comprising
further forming a first conductivity-type control layer which is connected to said base and wherein the breakdown voltage of the junction surface to the base is greater than a breakdown voltage of a junction surface of said base and said second collector.

28. The usage method according to claim 15, comprising:
forming a second conductivity-type base connected to a first conductivity-type emitter;
forming a first conductivity-type first collector connected to said base; and
forming a first conductivity-type second collector having impurity density higher than that of said first collector and being connected to said base.

29. The usage method according to claim 28, wherein
an area of a junction surface of said base and said first collector is smaller than an area of a junction surface of said base and said emitter.

30. The usage method according to claim 28, wherein
an area of a junction surface of said base and said emitter is smaller than an area of a junction surface of said base and said first collector.

31. The usage method according to claim 28, further comprising
forming a first conductivity-type control layer, having impurity density lower than that of said second collector and being connected to said base.
